(19) United States
(12) Patent Application Publication
(10) Pub. No.: US 2024/0333256 A1
(43) Pub. Date: Oct. 3, 2024

(54) DESIGN AND FABRICATION OF A NOVEL SENSOR BASED ON THE QUARTZ CRYSTAL RESONATOR TECHNIQUE TO DETECT BIOLOGICAL AND NON-BIOLOGICAL SYSTEMS

(71) Applicant: BOARD OF TRUSTEES OF THE UNIVERSITY OF ARKANSAS, Little Rock, AR (US)

(72) Inventors: Raad Adnan Abdulnabi Alawajji, Little Rock, AR (US); Ganesh K. Kannarpady, Little Rock, AR (US); Alexandru S. Biris, Little Rock, AR (US)

(21) Appl. No.: 18/619,347

(22) Filed: Mar. 28, 2024

Related U.S. Application Data
(60) Provisional application No. 63/455,620, filed on Mar. 30, 2023.

(51) Int. Cl. H03H 9/19; H03H 3/04; H03H 9/13

(52) U.S. Cl. CPC H03H 9/19; H03H 3/04; H03H 9/13

(57) ABSTRACT

A quartz crystal resonators (QCR) used as a sensor for quantitatively detection of a target. The QCR comprises a first electrode; a second electrode; a quartz wafer disposed between the first electrode and the second electrode; an immobilizing agent disposed on a surface of at least one of the first electrode and the second electrode; and a binding agent in association with the immobilizing agent; wherein the binding agent binds to the target.

### CROSS-REFERENCE TO RELATED PATENT APPLICATION

This application claims priority to and the benefit of U.S. Provisional Application No. 63/455,620, filed Mar. 30, 2023, which is incorporated herein in its entirety by reference.

### FIELD OF THE INVENTION

The present invention relates generally to sensors, and more particularly to designs and fabrications of a novel sensor based on the quartz crystal resonator technique to detect biological and non-biological systems/targets such as cells, proteins, markers and applications of the same.

### BACKGROUND OF THE INVENTION

The background description provided herein is for the purpose of generally presenting the context of the invention. The subject matter discussed in the background of the invention section should not be assumed to be prior art merely as a result of its mention in the background of the invention section. Similarly, a problem mentioned in the background of the invention section or associated with the subject matter of the background of the invention section should not be assumed to have been previously recognized in the prior art. The subject matter in the background of the invention section merely represents different approaches, which in and of themselves may also be inventions. Work of the presently named inventors, to the extent it is described in the background of the invention section, as well as aspects of the description that may not otherwise qualify as prior art at the time of filing, are neither expressly nor impliedly admitted as prior art against the invention.

Point-of-care (POC) diagnostics is gaining significant attention in the healthcare industry due to its easy access, low cost, portability, and fast turnaround time. Sensors developed based on platforms such as micro/nano electro-mechanical systems (MEMS/NEMS), and Quartz Crystal Resonators (QCRs) are the backbone of such POC tools. The recent global pandemic SARS-COV-2 has increased the importance of POC tools, which can enhance the detection, isolation, and prevention of spreading, and have proven effective in curbing the pandemic. Similarly, POC screening tools can significantly improve the quality of healthcare provided for terminal diseases such as cancer, where early detection is critical to a positive prognosis for the patient.

Circulating tumor cells (CTCs) are believed to be the main pathway toward metastasis, which is the growth of secondary tumors from cells that detach from the primary tumor. CTCs are responsible for around 90% of cancer-related deaths, so developing techniques for early CTC detection can help create strategic treatment plans to counter metastatic growth and increase patient survival. In recent years, many advanced methods have been developed to detect and isolate CTCs early for successful treatment. CTCs have different properties than normal cells. Various technologies have been applied to isolate them based on physical properties such as deformability, size, and electric charge, as well as biological properties such as surface protein expression. The most effective techniques combine physical and biological properties. However, CTC detection remains a challenge because the concentration of CTCs is as low as one cell among millions of healthy cells. Therefore, one must overcome their detection and isolation limitations to develop convenient, affordable, and sensitive CTC detection techniques.

Quartz crystal resonators (QCRs) have become a widely used analytical tool due to their sensitivity to mass variations as small as nanograms in various fields, such as thin film thickness monitors and quartz crystal microbalances (QCMs). In recent decades, several researchers have started using their unique potential in the field of biological sensors. Redpenning et al. studied the rate of attachment of osteoblast cells, which are bone-forming cells, to QCMs in an aqueous solution. They observed a direct relationship between changes in the resonant frequency and surface area coverage to monitor osteoblast cell growth over several weeks. Gryte et al. monitored the attachment and detachment of mammalian cells on metal surfaces in real time on the piczoelectrically active area of QCMs and observed that the anchoring and attachment of cells on the QCM surface caused a decrease in frequency. Fredriksson et al. characterized living cells using the QCM technique and found that by monitoring both the frequency change and energy dissipation, valuable information can be gathered on the cell-surface adhesion process. They also observed that by using a serum-free medium, small clusters of cells (less than 100 cells) could be detected. Additionally, they studied the cell attachment on QCMs in serum-containing media and proved that QCM could be an effective and powerful technique to monitor cell attachment and spreading, which can constitute a screening method in the biomaterials research area. Atay et al. used QCM to detect high metastatic human breast cancer cells. In their study, they deposited PHEMA nanoparticles on the surface of the QCM sensor to enhance its functionality with transferrin. The results showed that the sensor had high sensitivity and selectivity to discriminate MCF-7 cells from other cells they tested. In another study, Zhang et al. investigated the detection of breast cancer cells (MCF-7) in situ using QCM. They immobilized chitosan and folic acid conjugate on the QCM surface, which was used as a receptor to capture MCF-7 cells. The device showed a detection limit of around 430 cells per milliliter.

A typical QCR is made from a disc or rectangle of quartz crystal sandwiched between two circular metallic electrodes deposited using physical vapor deposition. The resonators are designed to oscillate at a fundamental frequency via the piezoelectric effect when voltage is applied to the excitation electrodes and can also operate at higher frequencies (e.g., 3rd, 5th, 7th, etc. harmonic modes) to provide higher mass sensitivity. In the 1950s, Sauerbrey theorized that adding or removing a small amount of mass from the surface of a quartz crystal electrode causes a shift in the resonance frequency. This theory established today's well-known mass-frequency relationship in QCRs.

$$\\ \begin{matrix}Δ f \approx \frac{- 2 {f}_{o}^{{}_{} 2} Δ m}{A \sqrt{{ρ}_{q} {μ}_{q}}} = - {C}_{f} Δ m & ( 1 )\end{matrix}$$

Where C_{f} is the integral sensitivity or Sauerbrey sensitivity constant (Hz.m²/kg), Δf is the frequency shift (Hz), fₒ is the resonant crystal frequency (Hz), Δm is the mass change (kg), and A is the active area (m²), ρ_{q} is the density (kg/m³), and μq is the shear modulus (N.m²) for AT-cut quartz crystal. Equation 1 is applicable in many cases, especially with uniform thin films produced by vacuum deposition; however, it is not a sufficient rule for all conditions.

Equation 1 is valid when the added mass is very small compared to the total mass of the crystal; in other words, when 4f <<fₒ. In addition, the homogeneous layer must cover the entire effective area in order to produce a change in mass (Δm). In this case, the QCR is considered an infinite plate vibrating in the fundamental thickness shear mode (TSM) with equal amplitude and phase at every point of the quartz plate surface. However, for many applications-such as electroplating and corrosion processes and some biological events—the added mass is not uniform and does not cover the effective electrode area completely or uniformly. As a result, the vibration amplitude distribution is not homogenous over the electrode area but instead reflects a Gaussian distribution. Therefore, the maximum vibration amplitude and, thus, the mass sensitivity will be in the center of the electrode region due to the energy trapping effect. This value will decrease towards the edges of the electrode. In other words, the frequency response would be higher for the same mass if the mass is attached to the center of the QCR electrode rather than the edge.

To overcome the limitation of QCRs where the mass sensitivity profile reflects a Gaussian distribution, many studies have been conducted to minimize or eliminate this contribution to the sensing area. One study used an analytical model to predict the mass sensitivity profile of a decorated ring electrode on the upper side of a QCR. The model analyzed 11-MHz Plano-Plano crystals with different mass loading factors and electrode diameters. The results showed that a material with a low mass loading factor (a very thin electrode) produces a uniform mass sensitivity in the center area, but such a thin electrode layer is not practical. The same theoretical model was used to study the mass distribution uniformity of 5-MHz crystals with a ring configuration and a large electrode area, but these dimensions caused the resonator to lose sensitivity. Another approach to minimize the mass sensitivity profile involved working at a higher frequency, such as the third or fifth overtone. The results showed that higher overtones produce a nearly uniform sensing area but also diminish mass sensitivity. The other researchers suggested that this issue could be overcome with new electrode designs, such as dot-ring or double-ring designs. However, the limitation of QCRs where the mass sensitivity profile reflects a Gaussian distribution has not been resolved yet.

Therefore, a heretofore unaddressed need exists in the art to address the aforementioned deficiencies and inadequacies.

### SUMMARY OF THE INVENTION

One of the objectives of this invention is to provide strategies to address the lack of circulating tumor cell (CTC) detection technology. This invention proposes using a mass-sensitive device based on quartz crystal resonators (QCRs) as a promising transducer for creating a biosensor for CTC detection. In one embodiment, the present invention discloses a mathematical model that analyzes the performance of Plano-Plano AT-cut crystals with a fundamental frequency of 6 MHz. The model aims to minimize the Gaussian distribution by creating a ring electrode QCR to achieve a uniform mass sensitivity distribution along its radius. In one embodiment, the present invention has conducted a comprehensive study with modifications and parameter optimization to predict the behavior of the modified resonators before fabrication. In one embodiment, the present invention has analyzed three designs-concentric identical-electrode (keyhole), a ring electrode, and modified ring electrode QCRs—to predict their mass sensitivity distribution and determine the possibility of achieving a uniform distribution. This would allow one to estimate the spatial mass distribution when deposited mass does not cover the sensing area uniformly or entirely. In one embodiment, the present invention has fabricated QCRs with three different electrode configurations and validated the model using an ink-dot method. In one embodiment, the present invention has further discussed the viability of the fabricated QCR designs as biosensors by modifying the surface with an anti-antibody selective layer for further investigation in CTC detection applications. In one embodiment, the present invention has used three cancer cell lines, MCF-7, PANC-1, and PC-3, to study the frequency response of 9 MHz ring electrode QCR and compared the data with that of 6 MHZ keyhole electrode QCR.

In one aspect, the invention relates to a quartz crystal resonators (QCR) used as a sensor for quantitatively detection of a target. The QCR comprises a first electrode; a second electrode; a quartz wafer disposed between the first electrode and the second electrode; an immobilizing agent disposed on a surface of at least one of the first electrode and the second electrode; and
a binding agent in association with the immobilizing agent, wherein the binding agent binds to the target.

In one embodiment, the first electrode comprises a ring configuration; and wherein the ring configuration has a ring configuration outer diameter and a ring configuration inner diameter.

In one embodiment, the ring configuration outer diameter is about 2.5 mm, and the ring configuration inner diameter is about 1 mm.

In one embodiment, the second electrode comprises a round configuration.

In one embodiment, the round configuration has a round configuration diameter about 2.5 mm.

In one embodiment, the second electrode comprises the ring configuration.

In one embodiment, the QRC further comprises a first sub-electrode disposed between the first electrode and the quartz wafer; and a second sub-electrode disposed between the second electrode and the quartz wafer.

In one embodiment, the target comprises at least one of cells, microbials, and large biological molecules; wherein the large biological molecules comprise proteins, DNAs, and RNAs.

In one embodiment, the target comprises circulating tumor cells.

In one embodiment, the immobilizing agent comprises 3-Δminopropyltriethoxysilane (APTES).

In one embodiment, the binding agent comprises an antibody.

In one embodiment, the QRC further comprises a linking agent; wherein the linking agent connect a Fc region of the antibody to the immobilizing agent.

In one embodiment, the linking agent comprises a fusion protein A/G.

In one embodiment, each of the first electrode and the second electrode comprises a gold layer.

In one embodiment, the gold layer of each of the first electrode and the second electrode are coated with titanium.

In one embodiment, the gold layer has a thickness between about 50 nm to about 120 nm.

In another aspect of the invention, a method for quantitatively detection of a target using a QCR comprises obtaining a first frequency reading of the QCR; exposing a sample containing the target to the QCR; incubating the QCR in association with the sample containing the target for an incubation period; fixing the target onto the QCR; washing the QCR with the fixed target; drying the QCR with the fixed target; and obtaining a second frequency reading of the QCR with the fixed target; wherein the QCR comprises a first electrode; a second electrode; a quartz wafer disposed between the first electrode and the second electrode; an immobilizing agent disposed on a surface of at least one of the first electrode and the second electrode; and a binding agent in association with the immobilizing agent; wherein the binding agent binds to the target.

In one embodiment, the method further comprises calculating a frequency shift by subtracting the first frequency reading from the second frequency reading.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment.

FIG. 1 illustrates cross section and front view of three QCR designs; (a) keyhole electrode QCR with radius a; (b) ring electrode QCR with inner radius a and outer radius b; and (c) modified ring electrode QCR with a first coating of solid electrodes on both sides (first layer I) and a second coating of ring electrodes on both sides with inner radius a and outer radius b (second metal layer II), and (III) non-electrode region.

FIG. 2 shows a systematic diagram of the experimental setup, and the inset shows a cross-section of the keyhole QCR sensor that is sealed between the PDMS sealing (above) and the O-ring (below).

FIG. 3 illustrates comparison of mass sensitivity distribution of 6-MHz Plano-Plano resonator for keyhole design (R=0.006), ring electrode (R=0.006), and modified ring electrode (R=0.0045); and the measured and predicted differential mass sensitivity of the three QCR designs as a function of radial distance.

FIG. 4A illustrates comparison of capture efficiencies of MCF-7 cells by control, direct, and indirect antibody immobilization strategies of APTES-modified ring electrode QCR.

FIG. 4B illustrates representation of direct and indirect anti-EpCAM antibody immobilization techniques of APTES-decorated 9-MHz ring electrode QCR.

FIG. 5 shows fluorescence images of three different cancer cell lines attached and fixed to a) 6-MHz keyhole QCR and b) 9-MHz ring electrode QCR, with an incubation time of 30 minutes and a magnification of 40×. The images represent a random area (scale of 20 microns) on the active regions of the quartz crystals and do not represent the total number of captured cells.

FIG. 6 shows charts reflecting frequency shift as a function of the number of attached cells on a) 6-MHz keyhole electrode QCR and b) 9-MHz ring electrode QCR for three different cancer cell lines, n=30.

FIG. 7 illustrates a schematic representation of the photolithography process for preparing the ring electrode QCR design.

FIG. 8 illustrates a process of reaction and attachment of APTES to the ring electrode QCR, R=NH₂.

FIG. 9A shows static contact angle of unsilanized ring electrode QCR sensor and 2% APTES-silanized ring electrode QCR as a function of reaction solvents at room temperature.

FIG. 9B shows static contact angle as a function of different concentrations of APTES-silanized ring electrode QCR in a toluene solvent at room temperature.

FIG. 9C shows static contact angle as a function of reaction temperature of 2% APTES-silanized ring electrode QCR in toluene solvent.

FIG. 10 shows AFM images (scan size 10 μm×10 μm) of (a) ring electrode QCR surface prior to silanization and (b), (c), and (d) APTES-silanized ring electrode QCR surface prepared with acetone, toluene, and chloroform, respectively, at room temperature.

FIG. 11 shows AFM images (scan size 10 μm×10 μm) of aminosilane-silanized ring electrode QCR surfaces in toluene solvent with different APTES concentrations: a) 0.5%, b) 1%, c) 2%, and d) 3% at room temperature.

FIG. 12 shows AFM images (scan size 10 μm×10 μm) of 2% APTES aminosilane-silanized ring electrode QCR surface in toluene at different reaction temperatures: a) 24° C. and b) 70° C.

FIG. 13 shows survey scan of control ring electrode QCR surface and 2% APTES-silanized ring electrode QCR surface prepared with acetone, chloroform, and toluene at room temperature.

FIG. 14 shows high-resolution spectra of N1s and C1s of 2% APTES-silanized QCR prepared in toluene for 2 h at different reaction temperatures: (a and b) 24° C. and (c and d) 70° C.

FIG. 15A shows fluorescence intensity as a function of different reaction solvents of APTES-silanized ring electrode QCR sensors at room temperature.

FIG. 15B shows fluorescence intensity as a function of different concentrations of APTES on APTES-silanized ring electrode QCR sensors in a toluene solvent at room temperature.

FIG. 15C shows fluorescence intensity as a function of reaction temperature of 2% APTES-silanized ring electrode QCR at different reaction temperatures in toluene.

FIG. 16A shows fluorescence images (magnification 40×) of a) FITC-labeled unsilanized ring electrode QCR and b, c, d) FITC-labeled 2% APTES-silanized ring electrode QCR prepared with acetone, toluene, and chloroform solvents, respectively, at room temperature.

FIG. 16B shows fluorescence images (40×) of FITC-labeled 2% APTES-silanized ring electrode QCR prepared in toluene solvent at reaction temperatures of a) 24° C. and b) 70° C.

FIG. 17 shows schematic representation of fluorescent Anti-EpCAM antibody immobilized on APTES-silanized ring electrode QCR.

FIG. 18 shows histogram for fluorescence intensity of a) APTES-silanized ring electrode QCR (control) and b) fluorescent anti-EpCAM antibody-labeled APTES-silanized ring electrode QCR.

FIG. 19 shows fluorescence images (40×) of a) APTES-silanized ring electrode QCR biosensor and b) fluorescence anti-EpCAM antibody-labeled APTES-silanized ring electrode QCR.

FIG. 20 shows survey scan of a) APTES-silanized ring electrode QCR and b) fluorescent anti-EpCAM antibody-labeled APTES-silanized ring electrode QCR.

FIG. 21 shows high-resolution spectra of N1s and C1s for a, b) APTES-silanized ring electrode QCR surface and c, d) fluorescent anti-EpCAM antibody immobilized on APTES-silanized ring electrode QCR surface.

FIG. 22 shows high-resolution spectra of a) N1s and b) C1s of PrAG deposited on APTES-silanized ring electrode QCR surface.

FIG. 23A shows frequency shift as a function of the number of attached cells on the 9-MHz ring electrode QCR sensor for three different cancer cell lines, n=30.

FIG. 23B shows frequency shift vs. percentage of total area of attached cells on 9-MHz ring electrode QCR for three different cancer cell lines, n=30.

FIG. 24 shows cell area distribution on 9-MHz ring electrode QCR sensor for three different cancer cell lines.

FIG. 25 shows AFM topography images (5 μm×5 μm) of a) direct anti-EpCAM antibody-immobilized APTES-silanized ring electrode QCR, and b) indirect anti-EpCAM antibody-immobilized APTES-silanized ring electrode QCR.

FIG. 26 shows fluorescence images of MCF-7 cell line attached to a) Control: APTES-silanized ring electrode QCR, b) direct anti-EpCAM antibody-immobilized APTES-silanized ring electrode QCR, and c) indirect anti-EpCAM antibody-immobilized APTES-silanized ring electrode QCR biosensor.

FIG. 27 shows frequency shift as a function of the number of captured MCF-7 cells by the anti-EpCAM-PrAG immobilized, APTES-silanized 9-MHz ring electrode QCR biosensor, n=30.

### DETAILED DESCRIPTION OF THE INVENTION

The invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

It will be understood that, as used in the description herein and throughout the claims that follow, the meaning of “a”, “an”, and “the” includes plural reference unless the context clearly dictates otherwise. Also, it will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

It will be further understood that the terms “comprises” and/or “comprising,” or “includes” and/or “including” or “has” and/or “having”, or “carry” and/or “carrying,” or “contain” and/or “containing,” or “involve” and/or “involving, and the like are to be open-ended, i.e., to mean including but not limited to. When used in this disclosure, they specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used in this disclosure, “around”, “about”, “approximately” or “substantially” shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated.

As used in this disclosure, the phrase “at least one of A, B, and C” should be construed to mean a logical (A or B or C), using a non-exclusive logical OR. As used herein, the term “and/or” includes any and all combinations of one or more of the associated listed items.

Embodiments of the invention are illustrated in detail hereinafter with reference to accompanying drawings. The description below is merely illustrative in nature and is in no way intended to limit the invention, its application, or uses. The broad teachings of the invention can be implemented in a variety of forms. Therefore, while this invention includes particular examples, the true scope of the invention should not be so limited since other modifications will become apparent upon a study of the drawings, the specification, and the following claims. For purposes of clarity, the same reference numbers will be used in the drawings to identify similar elements. It should be understood that one or more steps within a method may be executed in different order (or concurrently) without altering the principles of the invention.

In certain aspects, this invention relates to a novel approach in detection of biological systems/targets by using the quartz crystal resonators (QCR) techniques. The QCR is a mass-sensitive platform that can measure resonance frequency/resistance changes caused by a small change in mass. In one embodiment, the surface of the QCR will be coated with a proteins, antibodies, secondary antibodies, or marker that will specifically interact with the proteins, antibody, secondary antibodies cells, etc that the invention aims to detect, and which are specific to the disease or medical condition. The interaction will be therefore reflected by a reliable and measurable change in of mass, resulting in a change in the vibrating frequency of the QCR.

In one embodiment, this technique is used to detect but not limited to viruses (such Corona, influenza, etc), proteins (antibodies, specific proteins to diseases or medical conditions such as but not limited to cancer, TBI, heart conditions, etc), and even circulating tumor cells (CTCs—the main reason for metastasis).

In one embodiment, the present invention detects biological targets using the QCR and the method described below. In another embodiment, the QCR of the present invention detects non-biological targets, e.g. organic molecules, as well. In one embodiment, the QCR of the present invention detects alcohol, drug, toxic molecules in samples collected from a subject or surrounding environments.

In one embodiment, the technique uses a QCR to detect and quantify the interactions of certain biological and non-biological systems/targets (antibodies, proteins, secondary antibodies, etc) attached to the QCR surface and other biological systems/targets that need to be detected/quantified or markers that indicate their presence in blood, body fluids, inside and outside the body (proteins, antibodies, cancer cells, markers, bacteria, etc). In one embodiment, the present invention detects antibodies specific to the activity of viruses in the human and non-human biological systems/targets, and thus the invention detects the probability of the viruses' activity and also quantify it based on the amount of antibodies in the system, as detected by using the QCR. In another embodiment, this technique is used to detect proteins or markers associated with brain diseases and conditions such as traumatic brain injuries, such as S100B. In another embodiment, this technique is used to detect the markers associated with cancer, heart conditions, or other markers that are indicative of a medical disease or condition. In another embodiment this technique is used for the detection of CTCs out of blood, with or without removing blood cells before the analysis. Detecting CTCs early will help counter metastatic growth and increase patient survival. In addition, continuous monitoring of CTCs in the bloodstream will indicate how well a patient is reacting to the cancer treatment.

Cost, sensitivity, and simplicity make QCRs excellent biosensors. The present invention discloses two strategies to make the QCR a promising tool for advanced and enhanced detection. The present invention exemplifies the use of QCR for detection of CTCs, but the same approach can be taken to detect other biomarkers indicative of medical conditions.

In one embodiment, CTCs are confined at the center of a standard keyhole QCR using a custom sealing design, which helped provide a high frequency response and minimized random CTC distribution. However, the high standard deviation, attributed to random CTC distribution in the center of the QCR, still needed to be improved; therefore, an additional method was explored.

In another embodiment, the QCR of a ring electrode on the front side and a solid electrode on the back is adopted to promote uniform mass distribution. This ring electrode QCR displayed uniform mass distribution on the surface when the loading factor and ring electrode diameter were optimized. The 9-MHz ring electrode QCR device was successfully silanized with 3-aminopropyltrirthoxysilane (APTES), then CTCs were added to study the device's sensitivity. The results showed that the frequency shift was lincarly proportional to the number of attached cells for both standard and ring electrode designs. However, the standard deviation of a ring electrode QCR is small compared to a standard QCR because of uniform mass distribution. Anti-EpCAM antibodies were immobilized via direct and indirect techniques on the APTES-silanized ring electrode QCR to enhance CTC capture. Indirect immobilization (using PrAG) improved capture efficiency due to the highly oriented antibodies on the surface, caused by affinity binding between the antibody's Fc domains and the deposited PrAG. Based on these results, the QCR of the present invention represents a major step forward for applications involving random distribution, such as cancer cell research.

### Design and Modeling of New Quartz Crystal Resonators

The well-established Sauerbrey equation is applicable in many applications; for example, for uniform thin films produced by vacuum deposition, the equation can provide highly accurate information on the loaded mass weight or thickness. However, the Sauerbrey equation is not an absolute rule for all conditions, and some restrictions must be applied to it. First, it is only valid when the added mass is less than a small percent of the total mass of the crystal; in other words, when Δf<<fₒ. This condition is fulfilled by most scientific applications. Second, the homogeneous layer must cover the entire effective area, overlapping the electroded region, in order to produce the change in mass (Δm). As a result, the QCR is considered an infinite plate vibrating in fundamental TSM with equal amplitude and phase on every point of the quartz plate surface. In reality, for many applications—for example, electroplating and corrosion process and biological sensing—the added mass is not uniform and does not cover the effective electroded arca completely or uniformly. As a result, the vibration amplitude distribution is not homogenous over the electrode area but reflects Gaussian distribution instead, as mentioned in the previous chapter. The mass sensitivity profile of a QCR device is proportional to the square of its quartz particle displacement amplitude. Therefore, the maximum vibration amplitude and, hence, the mass sensitivity will be in the center of the electroded region (r=0) because of the energy trapping effect; this value will decrease towards the electrode edges.

To overcome this limitation of QCRs, many studies have been conducted to minimize or eliminate the Gaussian contribution on the sensing area. One study used an analytical model to predict the mass sensitivity profile of a new modified ring electrode on the upper side of a QCR. The model analyzed 11-MHz plano-plano crystals with different mass loading factors and electrode diameters. The results proved that a material with a low mass loading factor (very thin electrode) produces uniform mass sensitivity in the center area, but, unfortunately, such a thin electrode layer is not very practical. The same theoretical model was applied to study the mass distribution uniformity of 5-MHz crystals with ring configuration and a large electrode arca. However, those design dimensions caused the resonator to lose too much sensitivity. Another attempt to minimize the mass sensitivity profile involved working at a higher frequency, the third and fifth overtone. The results showed that using higher overtones produces a nearly uniform sensing area but diminishes the mass sensitivity. The researchers claimed that this issue can be overcome by new electrode designs—the dot-ring and double-ring designs.

Recently, Huang et al. introduced a ring electrode design to produce uniform distribution in 10-MHz crystals. They showed that a crystal with a 2-mm upper ring electrode and 5-mm outer electrode could achieve almost uniform mass distribution when the loading factor was equal to 0.0044. However, the theoretical results showed that the distribution was not totally uniform in the center of the electrode. Additionally, the design of the upper ring electrode would most likely introduce some variation in the response of the crystal resonator. The electrode in the belt defect region would be thinner than in the other parts of the ring, which can cause non-uniform distribution due to the change in the loading factor. Also, a comparison between the theoretical and experimental mass sensitivity distribution results was not provided.

### Fabrication of Quartz Crystal Resonators and Mass Distribution Measurements

### INTRODUCTION

Based on the application of the QCR, a variety of electrode materials and configurations can be used. The most common electrode type, the key-hole electrode, has identical circular electrodes on both sides of the quartz crystal. Another electrode design consists of two circular electrodes with a small electrode on the bottom and a larger electrode on the front. This design provides more stability to the resonator in a liquid environment by reducing the fringing field and increasing the quality factor. Different materials can be used to fabricate resonator electrodes depending on the goal of the QCR, such as gold, silver, copper, and indium tin oxide.

Most electrode designs are transferred onto the quartz crystal using a masking procedure, and then the electrodes are deposited by physical vapor deposition techniques such as electron beam and sputtering. However, this method is limited because some complicated electrode configurations, such as ring, double ring, multiple-electrode, and irregular electrode designs, cannot be fabricated easily by the regular masking procedure. In these situations, other techniques to transfer the electrode configuration to the quartz crystal should be used. For instance, dual and tetra electrode structures have been fabricated using screen printing with brilliant gold paste. In another study, a multichannel quartz crystal microbalance array with three pairs of electrodes was fabricated using photolithography to print the electrodes, followed by deposition of gold electrodes by a sputtering technique, then a lift-off process. The photolithography process, also known as optical lithography, is the method of transferring any geometrical shape generated on a photomask to the substrate. Compared with other techniques, photolithography has been proven to be a very flexible and precise method for any electrode configuration on any type or size of substrate. Therefore, in this chapter, photolithography, sputtering disposition, and lift-off processes will be utilized to fabricate the proposed electrode configurations for quartz crystal resonators.

### Chemical Materials

Concentrated sulfuric acid, hydrogen peroxide (30%), isopropanol, and acetone (certified ASC grade) were purchased from Fisher Scientific (USA). Deionized (DI) water was purchased from Mill-Q (USA). Lift-off resist (LOR 10A) was purchased from MICRO.CHEM (USA). Positive Photoresist (PPR) (MEGAPOSIT SPR 220-3.0) and tetra methyl ammonium hydroxide (MEGAPOSIT MF-26A developer) were purchased form Rohm and Haas Electronic Materials LLC (USA). A gold target, 2 inches in diameter, 99%, and a titanium target, also 2 inches in diameter, 99%, were purchased from Kurt J. Lesker Company (USA).

### Apparatus

Two plano-plano AT-cut blank quartz crystal wafers with fundamental resonance frequencies of 6 MHz and 9 MHZ, respectively, were purchased from Telemark Co. (CA, USA). The quartz wafers were 13.97 mm in diameter and had optically polished surfaces.

The photomask was designed according to our proposed electrode patterns (circular and ring electrodes) and manufactured by Front Range Photomask LLC (USA). A solar simulator (Abet technologies, USA) was used as the source of UV light to expose the photoresist layer. The following tools were also used: spin coater: Model Ws-400E-6Npp-LITE; digital hotplate: PMC 720; MCS plasma system: HF-3 multimode; chemical microbalance: Mettler Toledo model XS105 (Mettler-Toledo AG, Laboratory & Weighing Technology); and Jiusion USB microscope with mini camera (up to 1000× magnification). A Sharpie permanent marker, 140S, ultra-fine-point ˜300-μm tip, red color.

### Fabrication of Quartz Crystal Resonators

In order to prepare QCRs with specific designed electrodes, the standard photolithography process was utilized to transfer the electrode pattern to the bare quartz wafer, then physical vapor deposition was used to metalize the quartz resonator electrodes. All the process details are described sequentially in more detail below.

### Quartz Wafer Cleaning

The plano-plano AT-cut blank quartz wafer disks with diameters of 13.96 mm were cleaned with piranha solution (H₂SO₄/30% H₂O₂ with ratio 3:1 (v/v)) for 5 min. They were then cleaned with isopropanol, acetone, and DI water via sonication for 5 min and finally dried with compressed nitrogen air prior to use.

### Spin Coating LOR/PPR

The cleaned quartz crystal wafers were dehydrated at 200° C. on a hotplate for 30 min to remove any moisture. This step is necessary and recommended to enhance the LOR and PPR layers by removing the moisture. Then, the dehydrated quartz wafer was allowed to cool for 1 min. The LOR liquid was poured on the quartz wafer, which was then spun at 500 rpm for 5 sec followed by 3000 rpm for 40 sec. After that, the LOR-coated quartz wafer was baked on a hotplate at 170° C. for 5 min and left to cool on an aluminum plate for 1 min. Then, the PPR was poured on the quartz wafer and spun at 500 rpm for 5 sec followed by 3000 rpm for 30 sec to get a uniform PPR coating. Finally, the quartz wafer coated with LOR/PPR was baked on a hotplate at 110° C. for 90 sec in order to remove the excess solvent from the PPR layer.

### Alignment and Exposure

The photoresist is not soluble in photoresist developer. However, upon exposure to UV light, it becomes soluble, which is the basic principle of photoresist operation in photolithography. Contact lithography, in which the quartz wafer comes in direct contact with the mask, was utilized to pattern the electrode design shape due to the high resolution that this method provides. The quartz wafer coated with LOR/PPR was aligned on the designed photomask and then exposed to the UV light for 35 sec. After exposure, the quartz wafer baked at 90° C. on a hotplate for 45 sec and was left for a few hours before the next step.

### Development and Post-Bake

In order to control the development uniformity, the exposed quartz wafer was immersed in a 0.26-N concentration of tetra methyl ammonium hydroxide developer for 3-4 min to remove exposed LOR/PPR layers. Then, the quartz wafer was post-baked on a hotplate at 110° C. for 60 sec to harden the final electrode image design on the wafer to enhance its ability to withstand the deposition process.

### Electrode Metallization

The DC-magnetron sputtering system, equipped with a turbo molecular pump, was used to deposit the metal electrodes on the patterned quartz wafer. A gold target and a titanium target, both 2 inches in diameter, were mounted inside the deposition chamber. The targets faced the quartz wafers at a zero angle, and the distance between the targets and substrate holder was around 10 cm. After pumping the system down to 1.2×10⁻⁶ Torr, 10 sccm of argon gas was injected into the chamber through the mass flow controller (MKS instruments In.). The sputtering pressure was kept at 1.5×10⁻³ Torr, and the sputtering power was kept constant at 30 watts and 15 watts for the titanium and gold targets, respectively. The substrate holder rotation was kept constant at 5 rpm to achieve uniform deposition on the quartz wafers. The deposition rate of the gold and titanium was 0.4 Å/sec and 0.1 Å/sec, respectively; deposition rate and thickness were monitored with a quartz crystal deposition controller (model 880, Telemark, USA). First, the titanium interlayer was deposited to enhance gold adhesion to the quartz wafer surface, then gold layers of different thicknesses were deposited to prepare various QCRs.

### Strip PPR/LOR Layers

After the electrode metallization process was complete, the remaining PPR/LOR had to be removed to get the final QCR design. Wet stripping using an organic solution, acetone, was utilized to strip the PPR layer, leaving the final resonator design. However, because the acetone leaves some photoresist residue during stripping process, the final design was cleaned with a piranha solution (H₂SO₄/H₂O₂3:1) for 1 min to remove any remaining PPR/LOR residues.

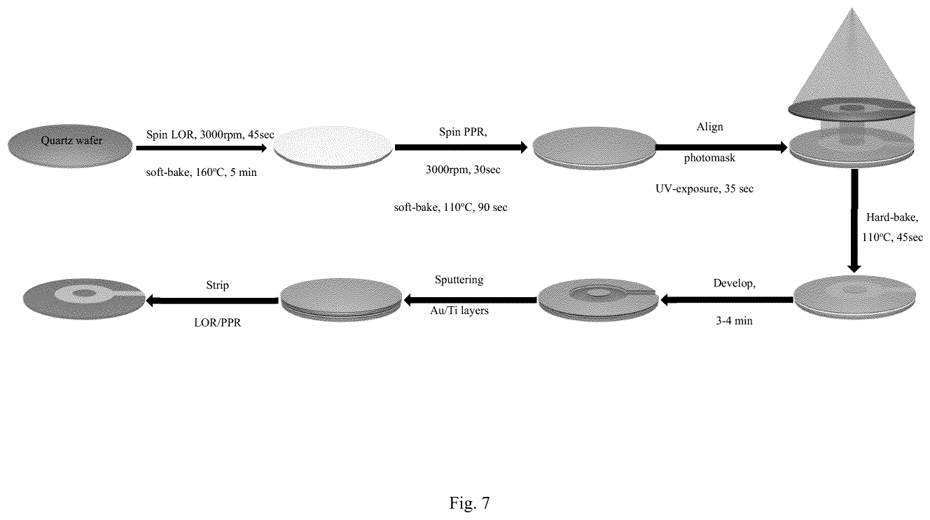

The entire QCR preparation process is illustrated in FIG. 7. Three different QCR designs were prepared—the identical-concentric electrode (keyhole) with a 2.5-mm radius for the upper and lower solid electrodes, the ring electrode with solid lower electrode radii of 2.5 mm, and the upper ring electrode (radius 1 mm (inner) and 2.5 mm (outer)). The first layer of the modified ring electrode is titanium with identical solid electrodes with radii of 2.5 mm, and the second layer is gold with identical upper and lower ring electrodes with inner radii of 1 mm and outer radii of 2.5 mm.

### Mass Sensitivity Distribution Measurement

The homemade setup was utilized to study the mass sensitivity distribution of different QCR designs. The QCR holder design consists of an HC-48/U holder, which has two micro-springs for easily mounting the resonator, fixed on a plastic platform and connected electrically to the male BNC connector on the side of the platform. The O-ring was mounted on the plastic platform, underneath the QCR, to support the resonator. Then, the holder was fixed on the x-y stage to move the resonator to the precise radial location. A red Sharpie permanent marker was used to place ink dots on the QCR surface. The pen was mounted on the z-stage and moved vertically to place ink dots on exact locations on the QCR surface. Mounting the pen in this way helped minimize the variation in dot mass caused by pressure, as it allowed the pen to fall freely on the resonator surface. A USB microscope with a mini camera (up to 1000× magnification) was used to observe the dots on the QCR surface each time to ensure that they were roughly the same size. The frequency was recorded using a QCA922 analyzer before and after dots were made on the resonator surface.

### Results and Discussion

Most experimental methods that have been used to map mass sensitivity distribution on QCR surfaces, including depositing or electroplating a small metal spot or applying a wire tip on the crystal surface, have some drawbacks. In contrast, the ink-dot technique has been proven to be a simple, effective, and reliable method to study mass sensitivity's radial dependence on the resonator surface.

First, in order to estimate the average mass of the ink dot, a few hundred dots were placed on the QCR surface using permanent marker, and the total mass of them was measured by the microbalance. It has been seen that the total weight of hundreds of deposited ink dots is around 100 μg, as measured by the microbalance. So, the average mass of an individual ink dot is estimated to be approximately 0.78±0.06 μg. In order to achieve accurate results, errors in dot position and dot mass must be minimized by repeating the measurements several times in each location. Then, the frequency shift (Δf) caused by each individual dot at each location in the long QCR radial direction is recorded. Interestingly, in this technique, the ink dots dry rapidly, allowing all the measurements to be completed in a short time. Furthermore, a small number of resonators are sufficient to complete the whole experiment because the ink dots can be removed easily by acetone or other chemical solvents. Finally, the ink-dot technique eliminates the stress and/or viscoelastic effect seen in alternative methods. That means that the recorded frequency shift is caused only by the mass of the ink dots.

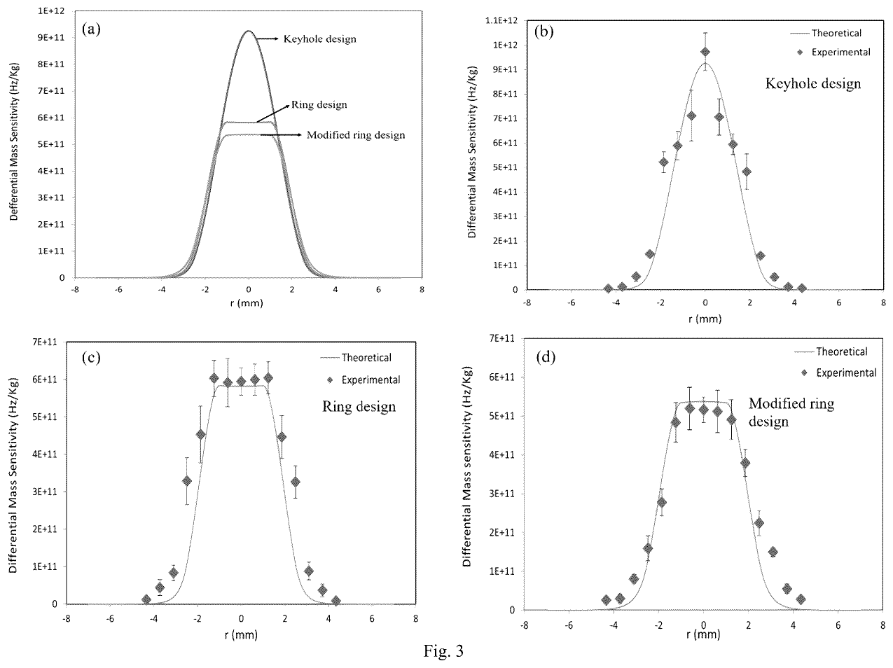

FIG. 3 compares the measured and predicted differential mass sensitivity of the three QCR designs as a function of radial distance. As expected, for the keyhole design with loading factor R=0.006 corresponding to 1100 Å gold layer and 150 Å titanium layer, the Gaussian profile was obvious and the mass sensitivity dropped gradually towards the electrode edge, as shown in FIG. 3 panel (b). This is attributed to the energy being primarily confined in the center of the electrode due to energy trapping. On the other hand, for the ring electrode design with the same loading factor, an inner ring diameter of 2 mm, and outer diameter of 5 mm, the mass sensitivity in the center produced a flat response. The modified ring electrode showed a flat region when the mass loading was around R=0.0045, as shown in FIG. 3 panel (c) (d). In other words, the center region of these designs (inner diameter: 2 mm) had the same mass sensitivity throughout its area because the acoustic waves had equal amplitude at each point (mass sensitivity proportional to the square of local wave amplitude).

It is clear from the figure that the measured mass sensitivity data follows the predicted trends for all designs. The expected deviation between measured and predicted data might be found in the exact mass and radial location of ink dots on the resonator surface each time. Though this effect was minimized in our setup, some errors cannot be avoided. Overall, the experimental data agreed with the predicted mass sensitivity and provided the same trend, as shown in FIG. 3.

### Conclusion

Three different quartz crystal resonator designs—keyhole, ring electrode, and modified ring electrode—have been fabricated successfully using the standard photolithography process. The metal electrodes with thickness corresponding to R=0.006 for keyhole electrode and ring electrode and R=0.0045 for modified ring electrode were deposited on blank plano-plano 6-MH2 quartz crystals successfully using DC-sputtering deposition. The ink-dot method was utilized to analyze the mass sensitivity distribution for the three QCR designs. The calculated results agreed very well with the experimental data obtained by ink dot for all the QCRs under investigation. Affordability and accuracy make the ink-dot method a very attractive technique for examining and calibrating the mass sensitivity of any quartz crystal resonator design. Finally, the new ring electrode and modified ring electrode QCR designs will be very interesting biosensor devices for CTC enumeration.

Detection of CTCs Using Ring Electrode QCR Biosensor

### INTRODUCTION

The present invention discloses the ability of QCR sensors to function as transducers to convert the mass change caused by CTCs to a readable frequency. The QCR is a sensitive tool for a low number of CTCs, though the device is limited by its poor selectivity; in other words, the device senses any mass attached to its surface, not just CTCs. Therefore, in order to make the ring electrode QCR device more efficient as a biosensor, it must be modified with a highly selective layer that enables it to capture only the targeted CTCs among healthy cells. This can be done by immobilizing the QCR surface with a biological selective layer—in our case, an anti-EpCAM antibody.

Immobilizing the antibody on the QCR directly can be achieved either by physical adsorption or chemical bonding. Our ring electrode QCR is composed of quartz, SiO₂, in the central area, and attaching the antibody layer directly to this surface (physical adsorption) is not favorable because it will tend to wash off due the weak bond between the antibody and the QCR surface; additionally, the antibody can even suffer a kind of denaturation process. Attachment of the antibody to the surface covalently is favorable due to the strong and stable linkage that is formed between the antibody and the supporting surface.

This section will explain the procedure used to associate the anti-EpCAM antibody covalently bond to the QCR surface, in which the quartz surface was modified with a self-assembled monolayer (SAM). The SAM technique is one of the most common and effective methods for creating a thin, well-ordered, reproducible layer suitable for antibody immobilization to improve biosensor functionality.

### Chemical/Biological Materials and Reagents

The following substances were purchased for this study. Anhydrous toluene (99.8%, extra dry), anhydrous acetone (99.8%, extra dry), anhydrous chloroform (99.8%, extra dry), methanol, detergent, chromic acid, hydrogen peroxide pellet, hexadecane, octadecyl trichlorosilane (OTS), carbon tetrachloride, and 3-aminopropyltriethoxysilane (APTES) were purchased from Fisher Scientific (USA). N-(3-dimethylaminopropyl)-N′-ethylcarbodiimide hydro-chloride (EDC), N-hydroxysuccinimide (NHS), phosphate-buffered saline (PBS, pH 7.4, 1×), sodium borate, and 0.5-M buffer solution (pH 9.0) were purchased from Alfa Aesar (USA). Alexa Fluor-594 antihuman CD326 (EpCAM) antibody and anti-human CD326 (EpCAM) antibody were purchased from Biolegend (USA). Anti-EpCAM monoclonal antibody (VU-1D9), Pierce recombinant protein A/G (PrA/G), and fluorescein isothiocyanate (FITC) were purchased from Thermo Scientific (USA).

### Analyzing Instruments

A drop contact angle instrument (DSA1, KRÜSS Co.) was used to measure the static contact angle (SCA) at room temperature. The instrument has a measuring range of 1-180° with ±0.1° accuracy. The objective lenses can be used to zoom up to 6× to obtain a clear, optimal image. The instrument has an x-y-z-movable stage and can carry samples that are up to 300 mm×∞×50 mm in size (W×D×H). A 10-μl droplet of water was put on the film using an automated syringe connected to a computer. Next, a light source, a set of optics, and a camera were used to take a clear image of the water droplet on the film surface. Finally, software (DSA1) was used to measure the baseline of the water droplet image and evaluate the contact angle.

The Thermo Scientific™ K-Alpha x-ray photoelectron spectrometer (XPS) is a compact, fully integrated monochromatic x-ray system. It features an Al Kα 1487-eV x-ray source and a 180° double-focusing hemispherical analyzer. The analysis area can range from 30 μm to 400 μm in a 5-μm step area. To prevent charging during sample analysis, low energy electrons (less than 1 eV) can be provided by a dual-beam flood source that couples with low energy ion beams. The XPS was used to generate wide-scan and high-resolution spectra to study the chemical components and elemental ratio of the surface coating. XPS analysis was conducted in an ultra-high vacuum chamber. Peak fitting, elemental ratio, and smart background subtraction were performed with Thermo Avantage software. Survey spectra (0-1350 eV) were analyzed to identify the elements present on the surface and estimate the element percentage from the normalized area under the curves. High-resolution spectra were used to identify the chemical bonds on the surface.

Atomic force microscopy (Dimension FastScan AFM, Bruker Co.) was used to analyze the morphology and roughness (RMS) of the silanized ring electrode QCR surface. A sharp silicon tip connected to a soft cantilever moving in x, y, and z directions was used to scan the surface area with different scan sizes by applying tapping mode. A slow scanning frequency (1 Hz) was used to create clear, high-resolution images. Finally, NanoScope analysis software (Ver. 1.5) was utilized to optimize the image quality.

### Experimental Procedures

### Chemical Modification of Ring Electrode QCR

In this study, a 9-MHz ring electrode QCR, functioning as a transducer, was utilized as the CTC biosensor device. Therefore, the surface of the QCR, an SiO₂ layer in the center of the device, needed to be modified in order to function as a biosensor for CTCs. After specific preparation steps were completed, silanization with APTES was done to accomplish this.

### Glassware Preparation for APTES Silanization

APTES reacts with glassware very fast, so glassware used to incubate an APTES solution must first be prepared carefully. The glassware, a Pyrex petri dish, was washed with a mixed solution of detergent and methanol (ratio 2:1) for 60 minutes at 50° C. on a hotplate, then washed thoroughly with DI water to remove organic contaminations. Next, the clean petri dish was immersed in chromic acid for 15 minutes then washed with DI water. Afterwards, the dish was sonicated with a 3-mM NaOH solution for 15 minutes then washed with DI water. Finally, the petri dish was dried with nitrogen gas and put on a 110° C. hotplate for 2 hours. After the petri dish cooled, it was filled with a solution containing 400 parts hexadecane, 60 parts CC14, 40 parts CHCl₃, and 0.5 parts OTS and incubated for 15 minutes in a glovebox under nitrogen atmosphere. Finally, the petri dish was washed several times with CHCl₃ to remove the excess OTS and heated at 120° C. on a hotplate for 2 hours.

### Cleaning and Activation of Ring Electrode QCR

The ring electrode QCR sensor was cleaned with isopropanol, acetone, and DI water for 5 minutes per cleaning agent using sonication. Then, the sensor was soaked in fresh piranha solution (3:1 sulfuric acid: 30% hydrogen peroxide) for 1 minute to remove most of the contamination from the sensor surface. Finally, the cleaned sensor was treated with 13.56-MHz RF-plasma with oxygen gas pressure at 100 mbar and plasma power at 100 mW for 5 minutes. This step helped remove any hydrocarbon contamination and activate the QCR sensor by increasing the hydroxyl groups on the surface.

### Silanization of Ring Electrode QCR

The effect of the reaction solvent, reaction temperature, and APTES concentration were examined. Many organic and inorganic solvents can be utilized to prepare silanization solutions to modify activated ring electrode QCR sensor surfaces. In this study, three anhydrous organic solvents-acetone, toluene, and chloroform-were used to prepare a 2% volume of APTES solution to coat the ring electrode QCR sensor at room temperature. To examine the effect of concentration, four different concentrations of APTES (0.5%, 1%, 2%, and 3%) were prepared in a toluene solvent at room temperature. To analyze the effect of reaction temperature, a solution of 2% APTES in toluene was utilized to modify the ring electrode QCR at two different reaction temperatures, 24° C. and 70° C.

The activated ring electrode QCR was incubated in the APTES silanization solution for 2 hours in a glovebox under nitrogen atmosphere. Then, the sensor was removed and washed with the same solvent twice, followed by ethanol and then DI water. Finally, it was dried with nitrogen compressed air to remove physiosorbed molecules. The sensor was kept on a hotplate at 120° C. for 6 hours to improve the APTES layer attachment on the QCR sensor surface.

### Wettability Measurement of APTES-Silanized Ring Electrode QCR

Contact angle measurements were performed by DSA1 using the sessile drop method to analyze the wettability behavior of un-silanized and APTES-silanized ring electrode QCR sensors with different organic solvents. A 5-μL water droplet was dispensed via computer-controlled syringe on the QCR sensor. An ACCD camera was utilized to capture images of the water droplet. The contact angle values represent at least three measurements per sensor, and all measurements were done at room temperature.

### FITC-Labeled APTES-Silanized Ring Electrode QCR

In order to prove the uniformity of the APTES coating on the QCR sensor and to confirm the presence of plenty of primary amino groups on the APTES-silanized sensor surface, FITC, the most common fluorescence dye, was added to the surface.

Stock solution was prepared by dissolving FITC powder in DMF at a concentration of 10 mg/mL and mixing until the FITC powder was completely dissolved. Then, 1 μL of stock solution was diluted with a 1.999-μL conjugation of buffer solution and sodium borate (50 mM, pH 8.5-9.0) to prepare the final 5-μg/ml fluorescence solution. After that, the unsilanized ring electrode QCR sensor, control sensor, and APTES-silanized ring electrode QCR sensors were incubated with 500 μL of the final fluorescence solution for 1 hour in the dark at room temperature. After that, to remove the excess and hydrolyzed FITC, all sensors were washed 3× with DI water with gentle shaking. Then, images were taken on many places with Olympus B5 and analyzed by ImageJ software.

### Fluorescent Antibody-Labeled APTES-Silanized Ring Electrode QCR

To monitor the conjugation of the anti-antibody to the APTES-silanized ring electrode QCR device, an Alexa Fluor-tagged anti-EpCAM antibody was applied to the QCR surface. The Alexa Fluor-tagged anti-EpCAM antibody can be immobilized on the APTES-silanized ring electrode QCR sensor using the well-known NHS/EDC reaction. The freshly prepared APTES-silanized ring electrode QCR sensor was immediately incubated with an EDC/NHS solution (250 mM/100 mM in PBS, PH 7.4) containing 10 μg/ml of Alexa Fluor-tagged anti-human CD326 (EpCAM) antibody for two hours at room temperature with gentle shaking. Then, the sensors were washed 2× with PBS, and, next, 2× with DI water. Finally, images of the fluorescence emitted by the Alexa Fluor-tagged anti-EpCAM antibody immobilized on the APTES-silanized ring electrode QCR were captured by a fluorescence microscope.

### Sensitivity of APTES-Silanized Ring Electrode QCR

The same cell lines, MCF-7, PANC-1, and PC-3, were used to study the sensitivity of the APTES-silanized 9-MHz ring electrode QCR.

### Anti-EpCAM Antibody Immobilization Strategies

The orientation of the anti-EpCAM antibody is considered a very critical, challenging step to the performance of the biosensor, as how well it captures CTCs depends on the proper orientation of the anti-antibody molecules. Therefore, in this study, two different methods were investigated to couple the anti-EpCAM antibody to the APTES-silanized ring electrode QCR.

1. The direct method, in which the anti-EpCAM antibody is covalently coupled directly to the APTES-silanized biosensor surface using EDC/NHS reaction. First, 10 μL of anti-EpCAM antibody (0.1 mg/mL) was diluted in PBS (0.1 M, pH 7.4) and then incubated with 10 μL of premixed EDC (5 μL of 0.4 mg/mL) and NHS (5 μL of 1.1 mg/mL) in MES buffer solution (0.1 M, pH 4.6) to activate the carboxyl groups on the anti-EpCAM antibody. Then, the EDC/NHS-activated anti-EpCAM antibody was added to the freshly prepared APTES-silanized ring electrode QCR biosensor for two hours at room temperature with gentle shaking. Then, the free sites were blocked to minimize unspecific reactions by applying 1% bovine serum albumin for 30 minutes. Finally, the sensors were washed 2× with PBS then 2× with DI water.

2. Indirect method, in which the PrA/G-mediated anti-EpCAM antibody is attached to the APTES-silanized biosensor surface. First, a 10-μL PrA/G solution (1.0 mg dissolved in 1.0 mL of 10-mM phosphate buffer, pH 7.4, and 1.0 mL of 10-mM Na-acetate buffer, pH 5.5) was activated by adding 10 μL of premixed EDC (5 μL of 0.4 mg/mL) and NHS (5 μL of 1.1 mg/mL) in MES buffer solution (0.1 M, pH 4.6) for 10 minutes at room temperature. Then, 50 μL EDC/NHS-activated PrA/G solution was incubated with the APTES-silanized QCR biosensor for 60 minutes at room temperature to covalently bond to the surface. The biosensor was then washed 2× with PBS to remove any excess unbonded PrA/G. After that, 5 μL of anti-EpCAM antibody (0.1 mg/mL) diluted in 0.1-M phosphate buffer, pH 7.4, was added to the PrA/G-immobilized biosensor for 1 hour at room temperature followed by washing 2× with PBS then with DI-water prior to use.

### Efficiency of Anti-EpCAM-Immobilized APTES-Silanized Ring Electrode QCR

After the anti-EpCAM antibody was immobilized on the APTES-silanized ring electrode QCR biosensor based on previous methods, the efficiency of the biosensor's ability to capture CTCs was tested. MCF-7 cells, breast cancer cells with high EpCAM expression, were applied to examine the cell capturing efficiency of the anti-EpCAM antibody-immobilized QCR biosensor. 50 μL MCF-7 cell suspension containing around 100 cells was incubated with the biosensors with and without anti-EpCAM antibody coating. The cells with the biosensors were incubated for 30 minutes to ensure antigen-antibody interaction. After that, the captured cells were fixed and stained.

### Results and Discussion

### Mechanism of the Bond of APTES on Ring Electrode QCR

One of the most popular SAMs in biochemistry is the organosilane. The organosilane is widely used as a coupling agent for silica-based materials to modify surfaces due to its bifunctional nature. Reacting an organosilane with a substrate helps make the surface's properties more useful for certain applications.

The simplest aminosilane molecule, APTES, has been used in the present project as a coating layer to modify a ring electrode QCR surface. In general, the reaction of APTES with the ring electrode QCR device involves four steps. In the beginning, hydrolysis of the three labile groups of APTES occurs. This step is followed by oligomer condensation. Then, the oligomer forms a hydrogen bond with the —OH groups on the ring electrode QCR surface. Finally, a covalent bond forms between the oligomer and the QCR substrate after curing or heating by concomitant loss of water.

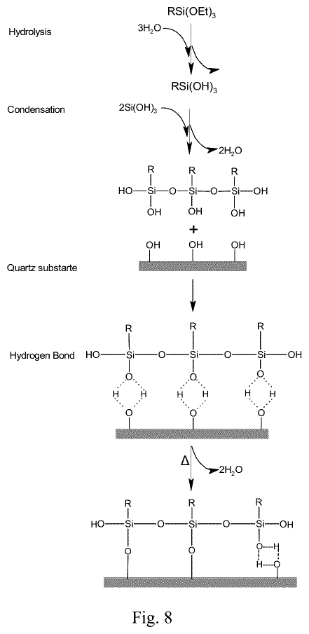

While APTES is considered the simplest organosilane and the most common aminosilane agent, it is also highly complex due to the presence of three ethoxy groups per molecule, in contrast to other aminosilanes such as APDMMS, which has just one methoxy group. Adding a small amount of water on APTES exploits the presence of the methoxy groups, potentially leading to a few different events between the APTES and the surface, such as covalent bond, 2D-self-assembly (horizontal polymerization), and 3D multilayers (vertical polymerization), as shown in FIG. 8. Additionally, a small amount of water at the surface interface can control the protonated amines and hydrolyzed ethoxy groups in the silane layers. However, too much water can cause uncontrolled reactions and formation of silane oligomers and polymers in bulk/solution. The reaction conditions, such as reaction time, temperature, silane concentration, pH, etc., have a significant effect on how the aminosilane layer forms on the surface; therefore, considerable efforts have been made to optimize these effects. Generally, anhydrous solvents with a small amount of water and a low concentration of silane are ideal for creating smooth APTES-based silane layers.

### Wettability of APTES-Silanized Ring Electrode QCR

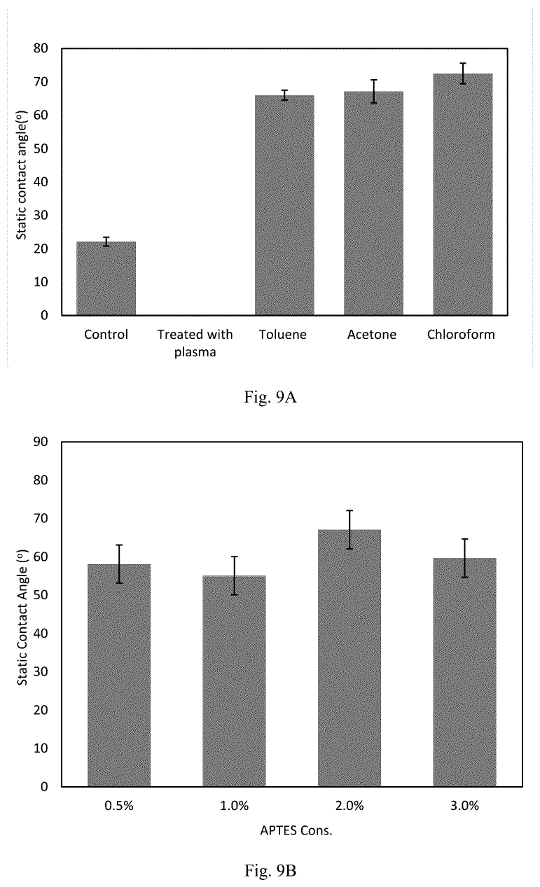

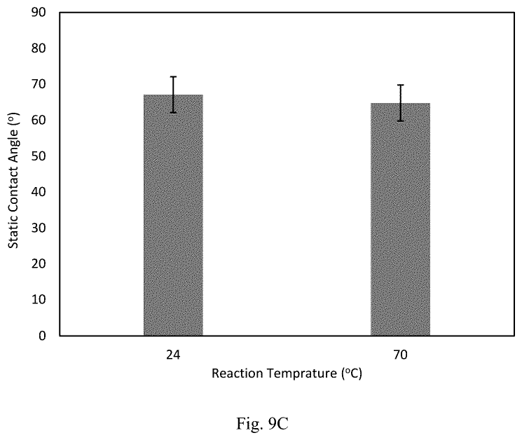

The water contact angle data for the APTES-silanized ring electrode QCR sensor surface in different organic solvents at room temperature is given in FIG. 9A. The contact angle measurements show that the unsilanized ring electrode QCR sensor, without plasma activation, is hydrophilic with a low contact angle, around 22±2°. This low contact angle is caused by the Si—OH groups on the surface; it is well known that this type of group is hydrophilic. After the ring electrode QCR sensor was activated with plasma, it exhibited super-hydrophilic behavior with zero contact angle. This is because the plasma treatment increases the active hydroxyl groups on the surface, which promotes the super-hydrophilicity. On the other hand, the APTES-silanized ring electrode QCR sensor with various anhydrous organic solvents had higher contact angles—66±1.5°, 67±3°, and 72±3.5° for toluene, acetone, and chloroform, respectively. The increase in contact angle values indicates the successful deposition of the APTES layer on the QCR sensor surface. Also, it seems that the type of reaction solvent has an effect on the wettability behavior of the APTES layer.

The effect of increasing the concentration of APTES on the wettability of the APTES-silanized ring electrode QCR sensor in the toluene solvent at room temperature was studied, as shown in FIG. 9B. There was minor variation between the static contact angles for different APTES concentrations. The 2% APTES concentration had the highest value, but generally, increasing APTES concentration did not have a significant effect on the sensor's wettability.

The effect of increasing the reaction temperature on the nature of APTES aminosilane coating was studied and is presented in FIG. 9C. The static contact angle for the APTES-silanized ring electrode QCR sensor prepared at a higher temperature, around 70° C., was slightly but not significantly lower than that of the aminosilane coating prepared at room temperature. This behavior caused no noticeable change in morphology, as will be discussed in the next section.

### Morphology of APTES-Silanized Ring Electrode QCR

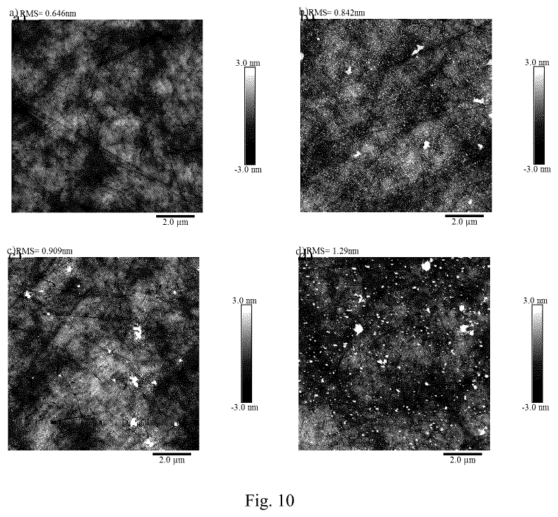

AFM was used to study the morphology of prepared aminosilane films on the ring electrode QCR sensor surface. The difference in the topography of the ring electrode QCR sensor surface before and after modification with APTES aminosilane via different solvents is shown in FIG. 10. The sensor surface (bare crystal wafer) without APTES modification was very smooth, with roughness (RMS) value being 0.646±0.002 nm, as shown in FIG. 10 panel (a). The sensor surface treated with APTES deposited using acetone had a slight increase in roughness, reaching around 0.842±0.01 nm. The aminosilane coating is clearly visible, with just few small agglomerate islands, as shown in FIG. 10 panel (b). The roughness was around 0.91±0.02 nm for the sensor surface silanized with APTES deposited via toluene solvent, as shown in FIG. 10 panel (c); the number and size of the islands on this sensor surface was low compared to the acetone solvent. The low roughness values confirm formation of a very thin APTES coating on the ring electrode QCR sensor surface. On the other hand, the ring electrode QCR sensor treated with APTES via chloroform had a higher roughness, around 1.29±0.05 nm, with more agglomerate islands than the other samples, as shown in FIG. 10 panel (d). This increased roughness indicates the formation of multiple layers of aminosilane on the sensor, and the presence of agglomerate islands is due to congested 3-D APTES polymerization.

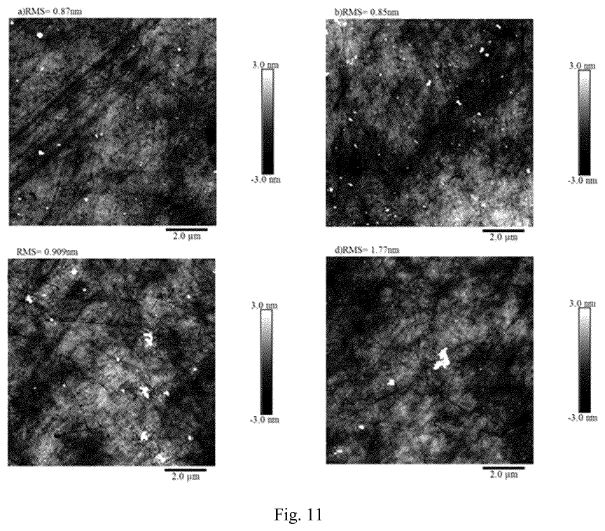

The effect of APTES concentration on the morphology of the ring electrode QCR sensor surface, prepared with a toluene solvent at room temperature, is depicted in FIG. 11. The AFM results showed that APTES concentration has a noticeable effect on the morphology of the aminosilane layers on the sensor. A low APTES concentration in the range of 0.5%-1% resulted in a smooth coating with low RMS values (˜0.87 nm, 0.85 nm) and very small—in size and quantity-APTES agglomerations, as shown in FIG. 11 panel (a,b). When the APTES concentration was increased to 2%, the aminosilane coating stayed smooth, with RMS in the range of 0.9 nm, but the agglomeration size increased as shown in FIG. 11 panel (c). Increasing the APTS concentration to 3% increased the surface roughness, with RMS reaching around 1.77 nm, and increased agglomeration size as shown in FIG. 11 panel (d). Clearly, increasing the aminosilane concentration promotes possible APTES polymerization. It is believed that the polymerization process takes place in the reaction liquid before it is attached to the surface. Consequently, these agglomerations will start to settle down on the formed aminosilane on the surface, creating various numbers and sizes of islands.

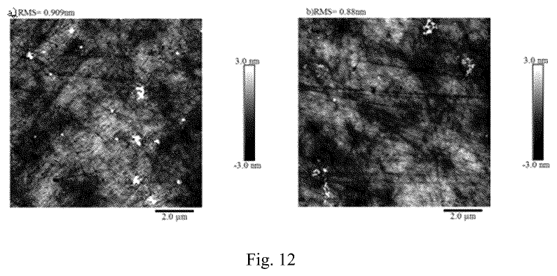

Another parameter that impacts the morphology of the aminosilane coating is reaction temperature. The effect of reaction temperature on the topography of an APTES-silanized ring electrode QCR (2% APTES) prepared in a toluene solvent is shown in FIG. 12. The FIG. 12 clearly shows that temperature has a major effect on the morphology of the prepared APTES coating. Raising the reaction temperature slightly reduced the surface roughness, from 0.909 nm (24° C.) to 0.88 nm (70° C.). Furthermore, there was a significant decrease in the number and size of agglomerations when the temperature increased.

### Surface Chemistry of APTES-Silanized Ring Electrode QCR

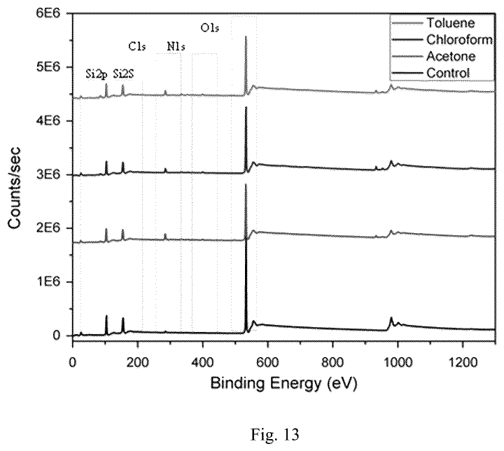

XPS was used to study the surface chemistry of the APTES-silanized ring electrode QCR sensor surface. Survey spectra were recorded to identify the elements present on the surface and estimate the element percentage from the normalized area under the curves. As shown in FIG. 13, the main elements on the unsilanized ring electrode QCR sensor were C1s, Si2p, and O1s, with a small amount of carbon being present due to adventitious contamination on the sensor surface. The 2% APTES-silanized ring electrode QCR sensors in different reaction solvents had nitrogen in addition to the above elements; furthermore, the amount of carbon was higher than in the unsilanized sensor. The presence of nitrogen and increase in carbon confirm the deposit of the aminosilane coating on the sensor. The elemental percentages of the APTES-silanized ring electrode QCR sensor in different organic solvents are given in Table 1.

TABLE 1
The elemental percentages of control ring electrode QCR and
APTES-silanized ring electrode QCR prepared with different
organic solvents for 2 h reaction time at room temperature

| | Elemental percentages % | | | |
|---|---|---|---|---|
| Samples | Si % | O % | C % | N % |
| Control | 33.47 ± 0.17 | 63.38 ± 0.13 | 3.15 ± 0.04 | — |
| Acetone | 31.18 ± 0.02 | 52.88 ± 0.46 | 14.28 ± 0.58 | 1.66 ± 0.13 |
| Chloroform | 30.52 ± 0.13 | 57.83 ± 0.69 | 9.89 ± 0.76 | 1.76 ± 0.06 |
| Toluene | 30.05 ± 0.3 | 55.48 ± 0.63 | 12.19 ± 0.83 | 2.28 ± 0.14 |

In addition to the effect of reaction solvent on the attachment kinetics of aminosilane, the effect of APTES concentration was examined. Table 2 shows the elemental percentages of APTES-silanized ring electrode QCR sensors with different concentrations of APTES. Though a small variation in elemental percentage was seen, it is clear from the table that the concentration of APTES does not have a significant effect on the surface chemistry of the aminosilane coating, especially on the N1s concentration.

TABLE 2
The elemental percentages of APTES-silanized ring electrode
QCR sensors prepared in toluene with different APTES
concentrations (2 h reaction time, room temperature)

| APTES | Elemental percentages % | | | |
|---|---|---|---|---|
| Cons. % | Si % | O % | C % | N % |
| 0.5 | 28.78 ± 0.22 | 58.87 ± 0.38 | 10.30 ± 0.49 | 2.06 ± 0.1 |
| 1 | 30.01 ± 0.18 | 58.26 ± 0.3 | 9.70 ± 0.57 | 2.04 ± 0.09 |
| 2 | 30.05 ± 0.81 | 55.48 ± 0.18 | 12.19 ± 0.83 | 2.28 ± 0.14 |
| 3 | 29.48 ± 0.3 | 58.85 ± 0.63 | 9.43 ± 0.49 | 2.25 ± 0.14 |

The effect of reaction temperature on the APTES-silanized ring electrode QCR surface is given in Table 3. The table shows that increasing the reaction temperature from room temperature up to 70° C. helped increase the concentration of N1s and C1s.

TABLE 3
The elemental percentages of 2% APTES-silanized
ring electrode QCR sensor prepared in toluene at
room temperature (24° C.) and at 70° C. for 2 h

| | Elemental percentages % | | | |
|---|---|---|---|---|
| Temp. ° C. | Si % | O % | C % | N % |
| 24 | 30.05 ± 0.30 | 55.48 ± 0.63 | 12.19 ± 0.83 | 2.28 ± 0.14 |
| 70 | 27.77 ± 1.97 | 53.60 ± 2.47 | 16.11 ± 3.62 | 2.51 ± 0.17 |

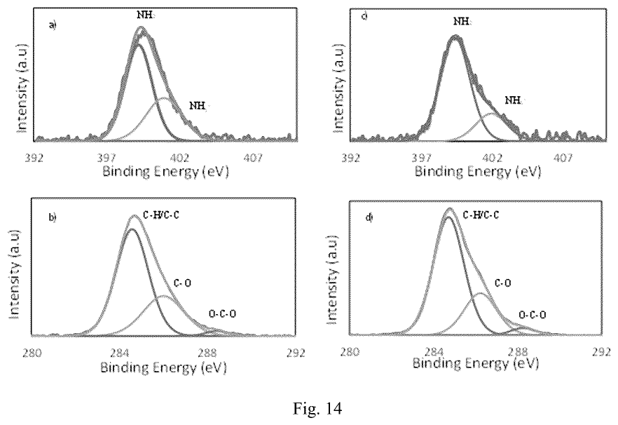

Survey scans can provide general information about the quantity of each element that exists on the APTES-silanized ring electrode QCR surface. Therefore, high-resolution scans were conducted to better understand the surface chemistry, such as the nature of APTES bonding with the QCR surface, and to estimate the primary active amine group quantity. FIG. 14 shows the high-resolution N1s spectra for aminosilane-silanized ring electrode QCR prepared with 2% APTES in toluene at different reaction temperatures, 24° C. and 70° C. Both curves show two major components related to the NH— bonds at different binding energies. The lower binding energy at 399 eV corresponds to the —NH₂ bonds, while the higher binding energy at 402 eV corresponds to the —NH₃⁺bonds. The major difference between the two spectra is the ratio between the —NH₂/—NH₃⁺. This ratio can provide the nature of aminosilane's reaction with the substrate. This ratio is around 1.86 and 2.97 for the APTES-silanized ring electrode QCR prepared at 24° C. and 70° C., respectively. The increase in this ratio as the reaction temperature increased indicates an increase in the primary amine —NH₂ groups compared to the —NH₃⁺. In other words, elevating the reaction temperature helps produce more ordered APTES aminosilane layers with a majority of —NH2 groups oriented outward of the QCR sensor surface.

### FITC-Labeled APTES-Silanized Ring Electrode QCR

In the field of biochemistry, FITC is the most common fluorescence reactive agent; it can bond with the amino groups on the surface of proteins, cells, tissue, and many types of aminosilane coupling agents. Thus, in order to prove aminosilane's attachment on the surface of the ring electrode QCR sensor and also to provide the best conditions to prepare plenty of reactive amine groups on the ring electrode QCR sensor, FITC dye was added to the surface. A FITC molecule has an excitation/emission spectrum peak of approximately 495 nm/519 nm, giving it a green color. It is able to react to one amino group of the APTES-silanized ring electrode QCR, forming a thiourca bond.

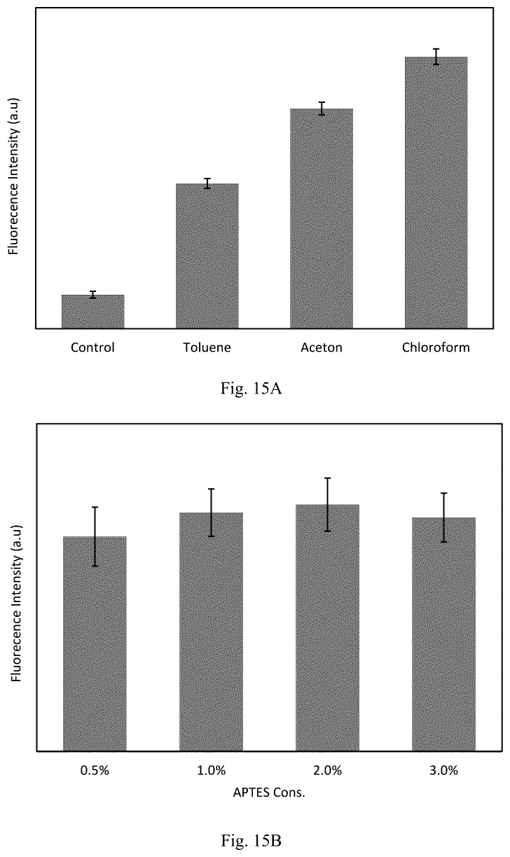

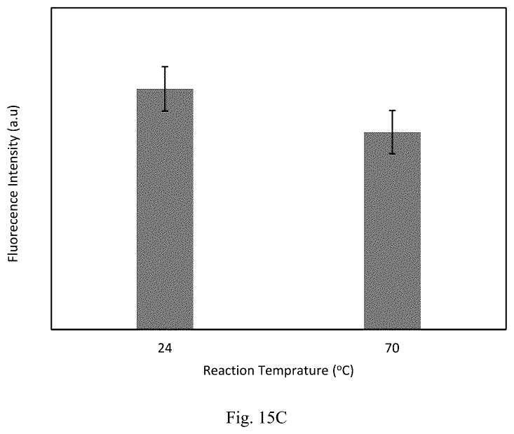

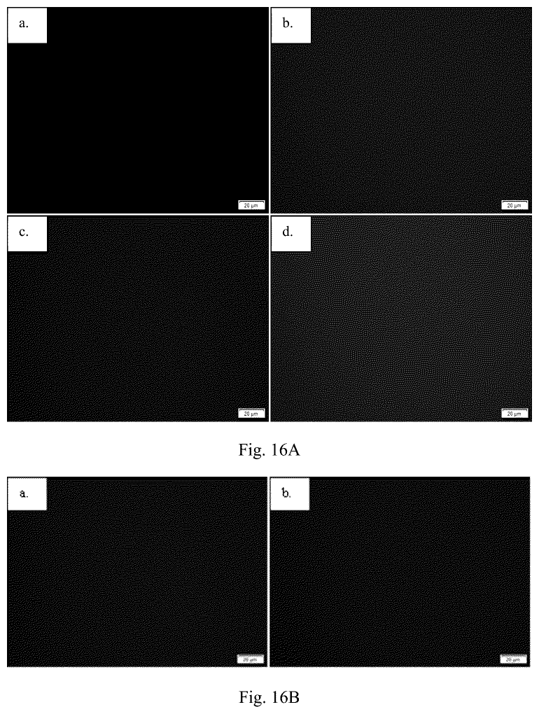

The fluorescent intensity of FITC-labeled unsilanized and FITC-labeled APTES-silanized ring electrode QCR surfaces prepared with different silanization solvents is shown in FIG. 15A. The unsilanized senor (control) had very low fluorescence intensity because the fluorescent dye does not react with the bare ring electrode QCR sensor surface. In contrast, the APTES-silanized ring electrode QCR sensor surface had higher fluorescence intensity because of the reaction of the fluorescence dye and silane layer, which formed an FITC-APTES complex on the surface.

The APTES-silanized ring electrode QCR sensor surface prepared with toluene shows high fluorescence intensity compared with the control. Acetone solvent preparation resulted in even higher fluorescence intensity, and the highest fluorescence intensity was seen with the chloroform solvent as shown in FIG. 15A. These increases in fluorescence intensity confirm that all the QCR sensors treated with APTES, regardless of solvent, were successfully coated with aminosilane. However, increasing the fluorescence intensity does not mean that the quality of the aminosilane coating is high. For example, chloroform-prepared multilayer APTES increased the fluorescence intensity, but multilayers are not preferable in many applications. In contrast, a monolayer of APTES on the ring electrode QCR sensor surface can be achieved with acetone and toluene. This behavior is consistent with the trend shown by AFM, which revealed that many 3D aminosilane structures had been formed using the chloroform, which causes higher fluorescence.

FIG. 15B shows the fluorescence intensity of APTES-silanized ring electrode QCR sensors with different concentrations of APTES in a toluene solvent at room temperature. By increasing the concentration of APTES more than 0.5%, the fluorescence intensity was increased slightly. However, further increasing the APTES concentration caused no significant change in the fluorescence intensity.

FIG. 15C shows the FITC fluorescence intensity as a function of the reaction temperature of an APTES-silanized ring electrode QCR (2% APTES) in a toluene solvent. The fluorescence intensity at 70° C. is lower than that of a sensor prepared at 24° C. This behavior can be attributed to the fact that higher temperatures produce a uniform and smooth aminosilane coating without APTES agglomerations, which leads to lower fluorescence intensity. In contrast, room temperature conditions result in a thick and rough aminosilane coating with many APTES agglomerations. These agglomerations help maximize the fluorescence intensity of the APTES-silanized ring electrode QCR, as confirmed by AFM data.

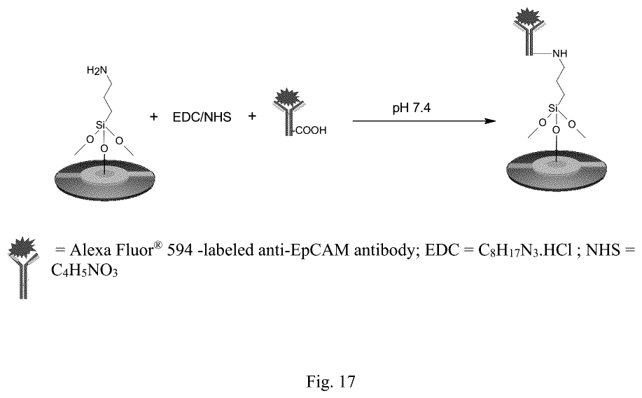

Fluorescence images of an unsilanized ring electrode QCR sensor and APTES-silanized ring electrode QCR sensors prepared with different organic solvents are shown in FIG. 16A. The unsilanized QCR sensor, as shown in FIG. 16A panel (a), appears completely dark because the FITC did not bond to the surface. APTES-silanized ring electrode QCR sensors prepared in different reaction solvents as shown in FIG. 16A panel (b-d), show clear intrinsic florescence intensity due to the formation of the FITC-APTES complex on the sensor surface.

FIG. 16B presents a fluorescence image comparison of 2% APTES-silanized ring electrode QCR sensors prepared in a toluene solvent at 24° C. and 70° C. The pictures indicate that the FITC fluorescence intensity of the QCR sensor prepared at 70° C. is lower than the intensity of samples prepared at 20° C.

### Fluorescence Antibody-Labeled APTES-Silanized Ring Electrode QCR

The most common reaction method used in biochemistry to conjugate proteins, enzymes, etc. is the EDC/NHS reaction. This reaction causes a robust amide bond to form between an antibody and another antibody or a substrate containing amine groups. EDC, which is a water soluble, zero-length crosslinking agent, was used to couple the carboxylic acid on the fluorescence anti-EpCAM antibody to primary amines on the APTES-silanized QCR surface. The carboxylic acid on the anti-EpCAM antibody is converted to a succinimide ester by the EDC coupling agent. The effect of the EDC-mediated coupling reaction can be maximized by adding the coupling NHS agent. Adding NHS helps stabilize the amine-reactive intermediate by converting it to an amine-reactive NHS-ester. Consequently, the amine-active intermediate spontaneously reacts with the primary amines on the APTES-silanized QCR biosensor to form a robust amide bond, as shown in FIG. 17.

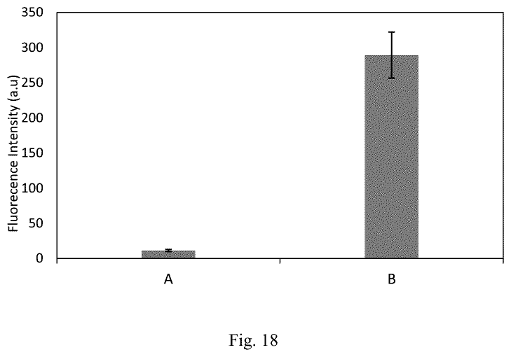

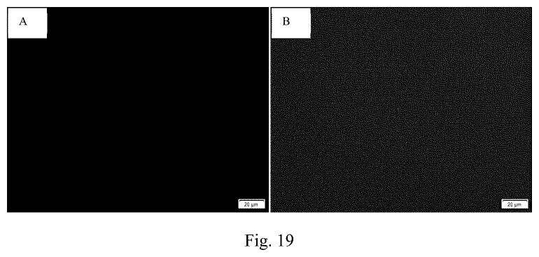

FIG. 18 shows the fluorescence intensity of APTES-silanized QCR biosensors without (control) and with fluorescence anti-EpCAM antibody. It is clear from the histogram that the APTES-silanized QCR biosensor labeled with the fluorescent anti-EpCAM antibody had very high fluorescence intensity (b) compared to the control, which had negligible fluorescence intensity. These results confirm that the fluorescent anti-EpCAM antibody had completely reacted and bonded with amino groups on the QCR biosensor surface by forming an amide bond. The fluorescence images of an APTES-silanized ring electrode QCR biosensor and a fluorescent anti-EpCAM antibody-labeled APTES-silanized ring electrode QCR biosensor are shown in FIG. 19. The APTES-silanized ring electrode QCR biosensor appears completely dark because no florescence emitted from the surface. In contrast, the fluorescent anti-EpCAM antibody-labeled APTES-silanized ring electrode QCR biosensorhad obvious, intrinsic florescence intensity due to the Alexa dye, which emitted a red color (617 nm) when excited with a 594-nm wavelength.

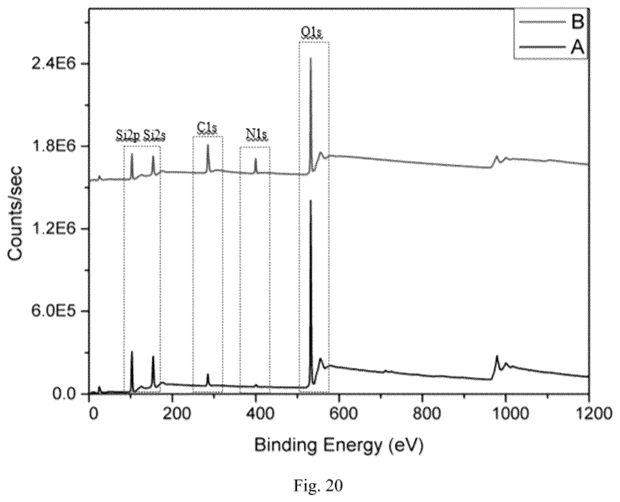

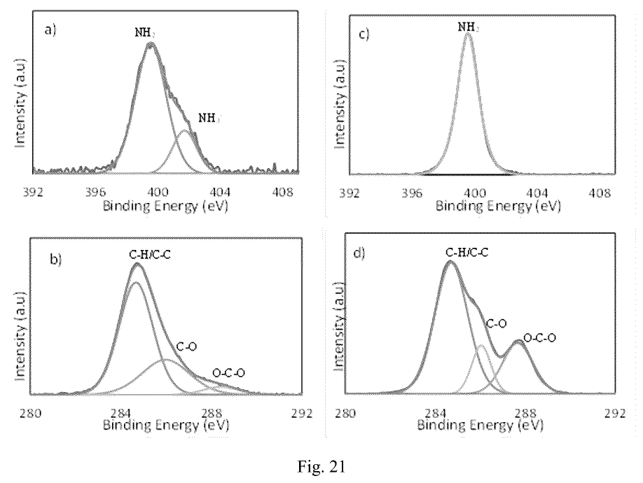

XPS analysis was conducted on the APTES-silanized and fluorescent anti-EpCAM antibody-labeled APTES-silanized QCR biosensors to compare the atomic composition on each surface. FIG. 20 shows the wide scan spectra for both samples; the N1s peak around binding energy 400 cV increased rapidly on the anti-EpCAM-labeled sensor. The C1s peak close to binding energy ˜286 eV also increased, while the Si2p and O1s intensities decreased. The presence of amide/peptide linkages in the anti-EpCAM antibody increased N1s and C1s peak intensities and decreased Si2p and O1s peak intensities, confirming the successful immobilization of the antibody on the biosensor. Table 4 presents the atomic composition of the elements on the APTES-silanized QCR biosensor surface without and with fluorescent anti-EpCAM antibody.

TABLE 4
The elemental percentages of A) APTES-silanized ring
electrode QCR and B) fluorescent anti-EpCAM antibody-
labeled APTES-silanized ring electrode QCR

| | Elemental percentages % | | | |
|---|---|---|---|---|
| Samples | Si % | O % | C % | N % |
| A | 30.05 ± 0.03 | 57.53 ± 0.44 | 10.72 ± 0.53 | 1.70 ± 0.09 |
| B | 20.89 ± 0.82 | 39.91 ± 1.23 | 31.67 ± 1.68 | 7.52 ± 0.43 |

The high-resolution spectra of N1s and C1s on the APTES-silanized ring electrode QCR surface and the fluorescent antibody-labeled APTES-silanized QCR biosensor are shown in FIG. 21. For the APTES-silanized ring electrode QCR surface, the N1s spectra's main peaks were located at 399.54 eV and 401.76 eV, which correspond to the primary amine groups (NH2) and protonated amines (NH₃⁺), as shown in FIG. 21 panel (a). The N1s spectra of the fluorescent anti-EpCAM antibody-labeled APTES-silanized ring electrode QCR biosensor had one sharp peak at 399.55 eV, which corresponds to the primary amine located on the protein's structure, as shown in FIG. 21 panel (c).

The C1s spectra of the APTES-silanized ring electrode QCR surface and the fluorescent anti-EpCAM antibody-labeled APTES-silanized ring electrode QCR biosensor are shown in FIG. 21 panels (b) and (d), respectively. Three major peaks arose from the APTES-silanized QCR biosensor, located at binding energies of around 284.67±0.2 eV, 285.98±0.32 eV, 288.42±0.12 eV for CH2 groups, C—O/or C—NH2 groups, and O—C—O groups, respectively. The C1s spectra of the fluorescent anti-EpCAM antibody-labeled APTES-silanized ring electrode QCR biosensor had the same number and location of peaks but with different intensity, as shown in FIG. 21 panel (d). The first peak, located at 284.71±0.8 eV, is attributed to CH₂ groups, while the second peak, centered at binding energy 286.4±0.51 eV, is attributed to the C—O/or C—NH2 groups; the third peak, located at binding energy 287.66±0.3 eV, corresponds to the O—C—O groups. This increase in the intensity of C—O/or C—NH2 and O—C—O groups could be attributed to the existence of these groups on the surface of the fluorescent anti-EpCAM antibody. This trend in N1s and Cls spectra confirms that the anti-EpCAM antibody was successfully immobilized on the APTES-silanized ring electrode QCR surface.

### Protein A/G Deposited on APTES-Silanized Ring Electrode QCR

The protein A/G (PrA/G) was deposited on the APTES-silanized ring electrode QCR surface to promote the anti-EpCAM antibody's attachment on the QCR surface through Fc domains. This makes the anti-antibody well-oriented and able to enhance the biosensor's performance. To confirm the binding of PrA/G on the surface, AFM and XPS analysis were conducted. AFM analysis with taping mode was used on dry and freshly prepared samples at room temperature. The surface without PrA/G clearly has a very uniform and smooth APTES coating with roughness around 0.9±0.09 nm. Once the PrA/G was deposited, the roughness of the surface increased rapidly to around 5.05 nm±0.5. This big difference between the roughness values indicates that the PrA/G successfully coated the surface. AFM analysis revealed the formation of many layers of PrA/G, in addition to some protein aggregation higher than 10 nm based on the high section profile. However, the PrA/G aggregates smaller than 10 nm are dominant and can be attributed to the formation of two or more PrA/G layers on the APTES-silanized surface. It has been reported that the first layer of PrA/G that firmly bonds to a supported surface does so in a very short time and, consequently, becomes a denaturated protein layer. In contrast, the second monolayer of the protein will be non-denaturated and ready to bond to the IgG.

Survey spectra were recorded to identify the elements present on the surface of PrAG deposited on APTES-silanized ring electrode QCR. The elemental percentages of APTES-silanized ring electrode QCR and PrAG deposited APTES-silanized ring electrode QCR is shown in Table 5. It is clear the increase in Nls, C1s percentage and decrease in Si2p, Ols percentage compared with APTES-silanized ring electrode confirms the successfully deposition of PrAG layer on APTES-silanized ring electrode QCR.

TABLE 5
The elementals percentage of A) APTES-silanized ring electrode
QCR and B) PrAG deposited on APTES-silanized ring electrode QCR

| | Elemental percentages % | | | |
|---|---|---|---|---|
| Samples | Si % | O % | C % | N % |
| A | 30.05 ± 0.3 | 55.48 ± 0.63 | 12.19 ± 0.83 | 2.28 ± 0.14 |
| B | 14.65 ± 0.79 | 30.96 ± 1.36 | 44.86 ± 2.05 | 9.54 ± 0.29 |

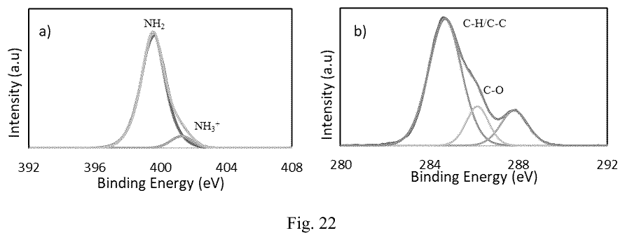

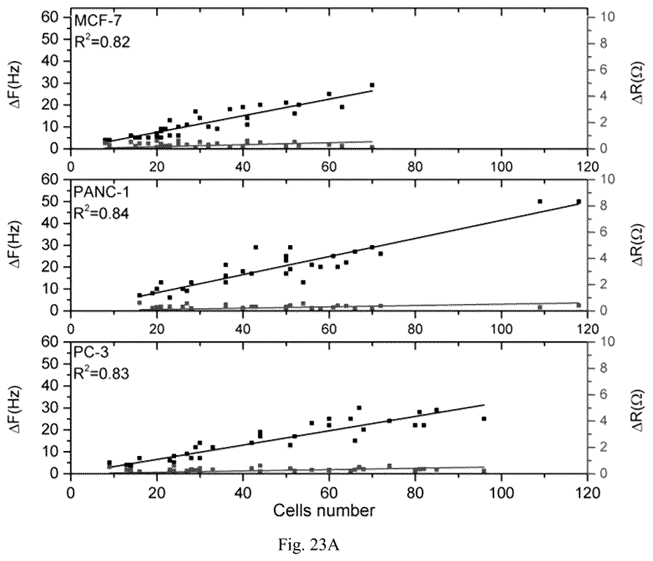

The high-resolution spectra of N1s and C1s of PrAG deposited on APTES-silanized QCR are shown in FIG. 22. The N1s curve shows two components related to the NH— bonds at different binding energies. The lower binding energy at 399.59 eV corresponds to the —NH₂ bonds, while the higher binding energy at 401.73 eV corresponds to the —NH₃⁺bonds. The presence of small peak at higher binding energy might be attributed to the protonated-NH2 in APTES layer. The C1s spectra of PrAG deposited APTES-silanized ring electrode QCR had the three peaks with different intensity, as shown in FIG. 22. The first peak, located at 284.65e V, is attributed to CH₂ groups, while the second peak, centered at binding energy 286.15 eV, is attributed to the C—O/or C—NH₂ groups; the third peak, located at binding energy 287.84 eV, corresponds to the O—C—O groups. This increase in the intensity of C—O/or C—NH₂ and O—C—O groups could be attributed to the existence of these groups on the surface of the PrAG. The trend of N1s and C1s spectra confirms that the PrAG successfully deposited on APTES-silanized ring electrode QCR surface.

### The Sensitivity of APTES-Silanized Ring Electrode QCR

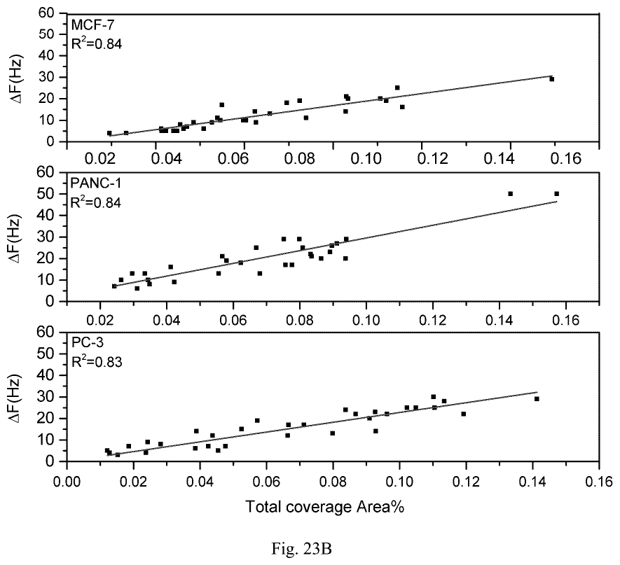

FIG. 23A shows the frequency shifts of the APTES-silanized 9-MHz ring electrode QCR with three different cancer cell lines as a function of the total number of attached cells. According to the FIG. 23A the frequency shift is proportional to the number of attached cells, as increasing the number of attached cells (and, thus, the mass) on the central area of the ring electrode QCR sensor caused an increase in frequency shift. The results indicate that the frequency shift caused by a single cell was around 0.39±0.09 Hz, 0.42±0.1 Hz and 0.32±0.08 Hz for MCF-7, PANC-1, and PC-3, respectively. The APTES-silanized ring electrode QCR provided good results regarding frequency shift, compared with a keyhole design. FIG. 23A also clearly shows that the shift in resonance resistance (ΔR) is negligible and does not change when the number of attached cells increases. This confirms that the fixed CTCs attached to the resonator behave as a rigid mass and that the frequency change is caused by the mass of the cells. This trend agrees with previous results found with the keyhole sensor design, though the standard deviation in this design is much better than that of the standard design. This can be attributed to the uniform mass sensitivity distribution on the 9-MHz ring electrode, which provided a frequency change based on the added mass. No effect was caused by CTC location because they were all located in the central area of the ring electrode.

For most applications of QCRs, the sensitivity of the resonator is described as the frequency shift with respect to the mass area; therefore, it is preferable to calculate the total cell area. To this end, the total area of attached cells was estimated using ImageJ software and divided by the electrode arca, 0.19 cm², to estimate the percentage of total attached cell arca. FIG. 23B shows the frequency shift plotted as a function of percentage of total area of attached cells on the ring electrode QCR sensor. The frequency shift was proportional to the total area of attached cells. In other words, the frequency shift increases when the percentage of surface covered by attached cells increases.

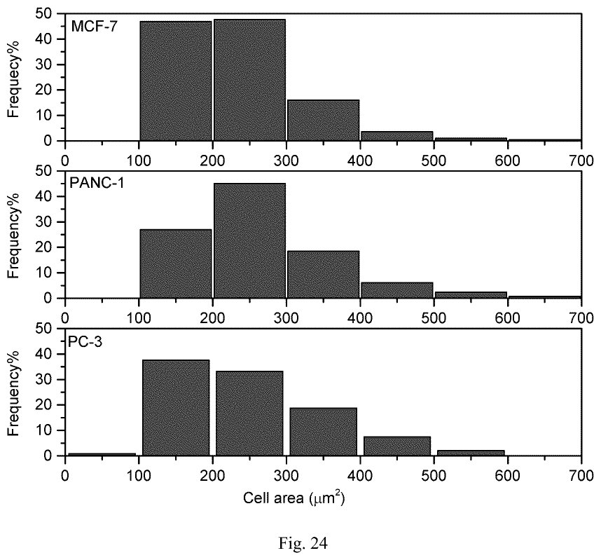

FIG. 24 shows the cell size distribution for MCF-7, PANC-1, and PC-3 cells attached to the keyhole electrode and ring electrode QCR sensors. On the 9-MHz ring electrode QCR sensor surface, most cells-more than ˜80%, ˜70%, and ˜70%-fell in the size range of 100-300 μm² for MCF-7, PANC-1, and PC-3, respectively. FIG. 5 shows the fluorescence images of phalloidin- and DAPI-stained MCF-7, PANC-1, and PC-3 cells attached to the 9-MHz ring electrode QCR biosensor surface.

### Anti-EpCAM-Immobilized APTES-Silanized Ring Electrode QCR Efficiency

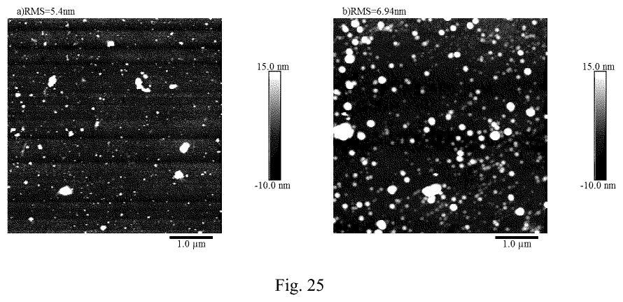

The efficiency of biosensors depends on the activity of the selective layer immobilized to the biosensor surface. Therefore, to maximize the CTC capturing efficiency of the ring electrode QCR biosensor, the anti-EpCAM antibody layer should be immobilized in such a way that their active sites are ready to interact with the antigens on the targeted CTCs. FIG. 25 shows the topography of anti-EpCAM antibody immobilized onto APTES-silanized ring electrode QCR surface by direct and indirect methods. Both methods show granular structures of the anti-EpCAM on both surfaces with various sizes. It seems using PrAG, indirect method, as an intermediated layer helps to organize the EpCAM antibodies on the PrAG deposited on APTES-silanized ring electrode QCR by improving the surface covering compared with direct method which shows less covering quality. The roughness of indirect method shows a little higher around RMS 6.94 nm compared with direct method which is around RMS 5.40 nm. Though, the AFM data provide a roughly information regarding the covering and the uniformity of anti-EpCAM antibody on the surface but the valuable information regarding the activity of antibody cannot be obtained based on AFM data. Therefore, practical technique to provide information about the antibody activity is still needed and there are a lot of efforts to introduce such technique for further investigations.

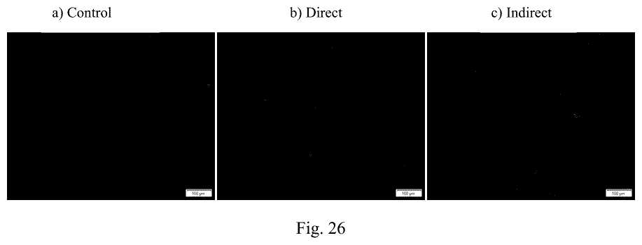

The ring electrode QCR, immobilized by direct and indirect methods with an anti-EpCAM antibody, was tested to study its capacity to capture MCF-7 cells. The cells highly overexpress epithelial cell adhesion molecule (EpCAM), which binds with anti-EpCAM antibodies effectively. FIG. 26 shows a representative image of MCF-7 cells stained with DAPI captured by the 9-MHz ring electrode QCR.

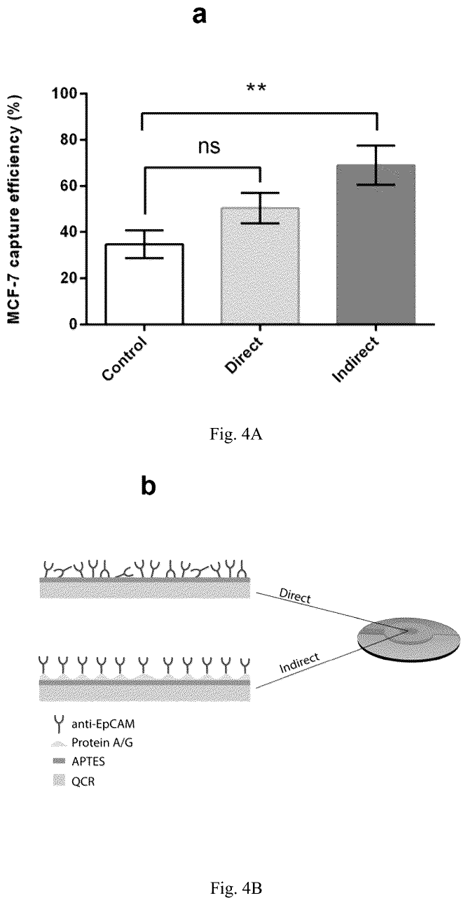

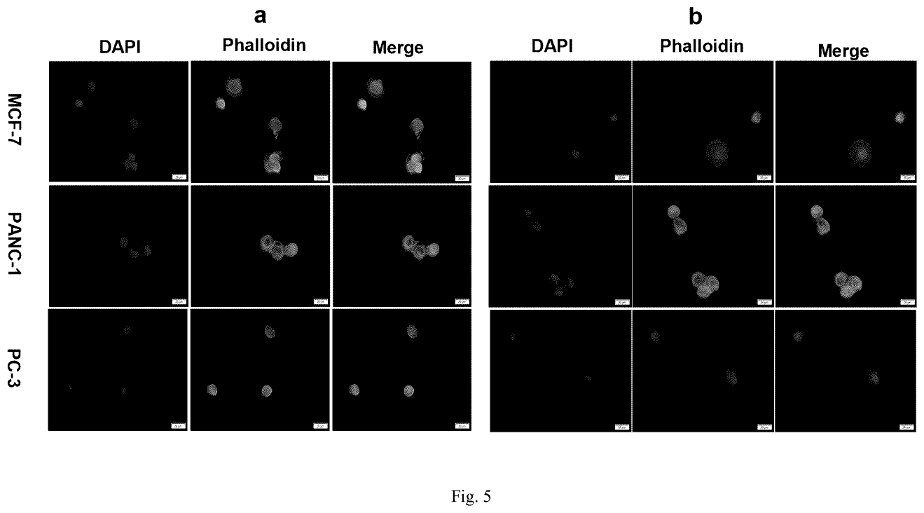

FIG. 4A presents the MCF-7 capturing efficiency of different 9-MHz ring electrode QCRs, representing the mean values of three separate experiments. According to the figure, the APTES-silanized ring electrode QCR without anti-EpCAM antibody (control) had a low number of captured cancer cells—to around 33%—which is attributed to the nonspecific interaction between the adherent MCF-7 cells and the biosensor surface. In this case, the attachment of the cells depended totally on the ability of MCF-7 cells to adhere to the APTES-silanized ring electrode QCR surface. The capture efficiency increased slightly but not significantly—to around 50%—after anti-EpCAM antibodies were covalently bound to the APTES-silanized ring electrode QCR. The slight increase in efficiency is due to the fact that the anti-EpCAM antibody layer helps promote surface binding of MCF-7 cells via antigen-antibody binding. However, during direct immobilization, some anti-EpCAM antibodies might bind covalently to the APTES layer through antigen binding active regions, which may hinder the antibody active sites, as represented in FIG. 4A. Consequently, they may lose their enhanced ability to capture cancer cells, which can explain the low capture efficiency. Therefore, in order to maximize the biosensor efficiency, the antibodies must maintain their activity during the immobilization process to the solid support surfaces.

Indirect immobilization of the anti-EpCAM antibody to the APTES-silanized ring electrode QCR using PrAG mediation overcame the random antibody orientation issue and showed higher capture efficiency. Recombinant PrAG is a genetically engineered protein that joins IgG binding domains of protein A and protein G, which are extracted from the surface of staphylococci and streptococci. The PrAG particularly binds to the Fc domain of various subclasses of IgG, and the advantage of PrAG over individual proteins A or G is that it covers almost the whole range of the subclasses of IgG and is less sensitive to pH variation. Therefore, covalently binding this protein mixture to the APTES-silanized ring electrode QCR biosensor helps maintain the activity of the anti-EpCAM antibody. The increased efficiency of the resulting QCR biosensor confirms that the anti-EpCAM antibody layer was very well-oriented on the sensing area of the biosensor. The highly well-oriented antibody, as shown in FIG. 4B, was probably responsible for improving the antigen-antibody binding. This good orientation is related to the strong affinity bonding between Fc domains of the anti-EpCAM antibodies and the PrAG deposited on the QCR biosensor surface. The well-oriented antibodies most likely facilitate the attachment of MCF-7 to the biosensor surface through antibody-antigen interaction, which explains the improvement in capture efficiency. It is noteworthy to mention that optimizing some parameters could improve the quality of the PrAG layer, which would improve the biosensor's performance.

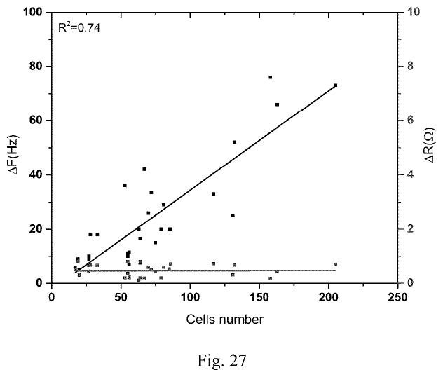

Next, the sensitivity of the APTES-silanized ring electrode QCR with anti-EpCAM antibody immobilized on PrAG was measured for many experiments with various numbers of MCF-7 cells, in the range of 50-250 cells. The frequency F1 was recorded for the control QCR biosensor, which was the APTES-silanized ring electrode QCR with anti-EpCAM antibody immobilized on PrAG, and the frequency F2 was recorded for the same QCR design after incubation with MCF-7. The frequency difference (ΔF=F2−F1) represents the frequency shift caused by the total mass of MCF-7 cells captured by the biosensor. FIG. 27 shows a linear relationship between the change in frequency (ΔF) and the number of attached cells. Compared with the APTES-silanized electrode QCR data, the R² was lower here because of the variation in the mass of the PrAG and Anti-EpCAM layers. The average frequency change per one cell was around 0.35±0.15 Hz. As seen and explained before, no change in the resonance resistance (ΔR) was seen when the number of attached cells was increased.

### Conclusion

For the first time, a 9-MHz plano-plano quartz crystal sandwiched between a ring electrode on one side and a solid circular electrode on the other has been introduced as a transducer for CTC detection. A thin, homogenous APTES coating on the ring electrode QCR device was achieved by optimizing reaction parameters such as temperature, APTES concentration, and solvents. The sensitivity of the APTES-silanized ring electrode QCR showed a linear relationship between frequency shift and the number of cancer cells attached. Additionally, the variation in resistance when the attached cells increased was negligible. While the resonance resistance remained unchanged, the change in the resonance frequency shift caused by increasing the attached CTC mass confirms that the cells behave as a rigid mass on the surface upon drying. In addition, the standard deviation for the frequency response of the ring electrode was much better than the keyhole design. This is mainly because the Gaussian distribution profile was removed in the center of the ring electrode.

An anti-EpCAM antibody was immobilized on the APTES-silanized ring electrode QCR successfully, with two strategies being used to improve the device's capture efficiency. Direct immobilization was done by covalently binding the antibody to the QCR. Indirect immobilization was done using a PrAG layer deposited on the QCR, which resulted in higher CTC capture efficiency than the direct immobilization method. The sensitivity of the ring electrode QCR prepared by the indirect method shows that the ΔF was around 0.35±0.15 Hz per one MCF-7 cell with no noticeable change in ΔR. This new biosensor is a significant move forward for clinically relevant CTC detection devices.

These and other aspects of the present invention are further described below. Without intent to limit the scope of the invention, exemplary instruments, apparatus, methods and their related results according to the embodiments of the present invention are given below. Note that titles or subtitles may be used in the examples for convenience of a reader, which in no way should limit the scope of the invention. Moreover, certain theories are proposed and disclosed herein; however, in no way they, whether they are right or wrong, should limit the scope of the invention so long as the invention is practiced according to the invention without regard for any particular theory or scheme of action.

### EXAMPLE

### Materials and Methods

### Mathematical Modeling of QCR Mass Sensitivity

The size, shape, and thickness of electrodes play a crucial role in the spatial mass sensitivity of QCR. However, changes in electrode configuration can affect the quality factor, potentially reducing the usefulness of QCRs as sensors. The present invention finds an optimal thickness of electrodes through mathematical modeling that strikes a balance between a reasonably high-quality factor and minimal non-uniformity in radial mass sensitivity. The Sauerbrey equation states that the integral sensitivity (C_{f}) can be calculated by integrating the differential sensitivity function (S_{f}) across the overlapping electrode area, as follows:

$$\\ \begin{matrix}{S}_{f} = \frac{{\vert \tilde{u} ( r ) \vert}^{2}}{2 π {\int }_{0}^{2 π} r {\vert \tilde{u} ( r ) \vert}^{2}} {C}_{f} & ( 2 )\end{matrix}$$

The differential sensitivity function (S_{f}) represents the mass sensitivity expressed in Hz/kg. u(r) represents the particle displacement amplitude on the surface, and r denotes the distance from the center of the crystal. The dependence of S_{f} is solely on the radial distance r, and it is unaffected by the angular distribution of the crystal plane. Therefore, one must determine the crystal's particle displacement amplitude u(r) to calculate the mass sensitivity.

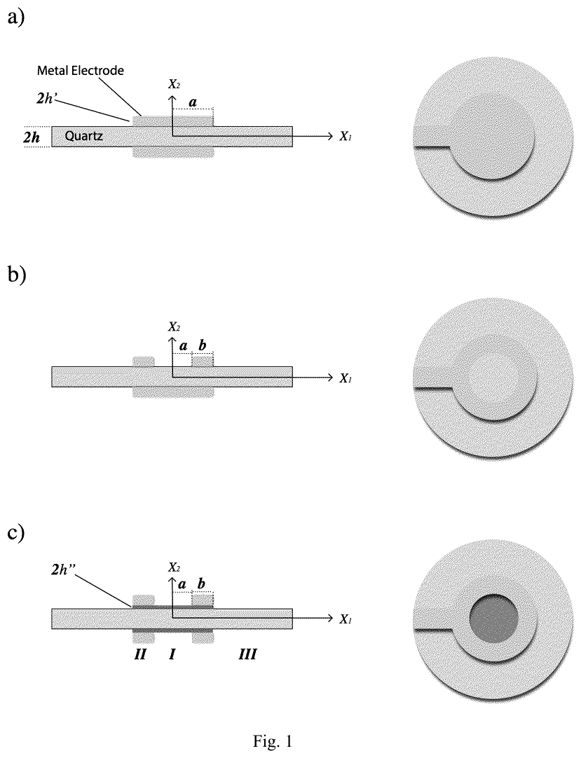

FIG. 1 shows cross-section and front view of three QCR designs: a) keyhole electrode QCR with radius a; b) ring electrode QCR with inner radius a and outer radius b; and c) modified ring electrode QCR with a first coating of solid electrodes on both sides (first layer I) and a second coating of ring electrodes on both sides with inner radius a and outer radius b (second metal layer II), and (III) un-electrode region.

In one embodiment, the present invention considers a two-dimensional AT-cut quartz wafer with a thickness of 2 h in the x₂ direction and extending infinitely in the x₃ direction. As shown in FIG. 1, metal electrodes of 2 h′ thickness are coated on a limited portion of the AT-cut quartz wafer. Due to the different mechanical constants (elastic and inertial) in the electrode region (I), the overlap of the upper and lower electrodes in the partial electrode region (II), the electrode tab, and the no-electrode region (III), the bar crystal exhibits varying characteristics. As a result, three distinct cut-off frequencies arise on the coated quartz crystal: the cut-off frequencies of the no-electrode region (III), the electrode region (I), and the region II beneath the electrode tabs in the partial electrode region. Despite the electrodes being coated with a very thin metal, these cut-off frequencies, designated ω_{c}^{u}, ω_{c}^{e}, and ω_{c}^{p}, are close to each other in each region. At a specific excitation frequency, a standing wave can be generated on the electrode region of the AT-cut crystal, and the following equation can describe its time-varying field.

$$\\ \begin{matrix}{u}_{1} ( {x}_{1} , {x}_{2} , {x}_{3} , t ) = {\tilde{u}}_{1} ( {x}_{1} , {x}_{3} ) sin ( {k}_{2} {x}_{2} ) {e}^{{}_{} j ω t} & ( 3 )\end{matrix}$$

Where k₂ is the shear horizontal acoustic wave number in the x₂ direction, and w is the angular excitation frequency (ω)=2πf). The acoustic wave equation can be simplified as follows.

$$\\ \begin{matrix}( \frac{{C}_{11}}{{C}_{44}} ) \frac{{\partial }^{{}_{} 2} {\tilde{u}}_{1}}{\partial {x}_{1}^{{}_{} 2}} + ( \frac{{C}_{55}}{{C}_{66}} ) \frac{{\partial }^{{}_{} 2} {\tilde{u}}_{1}}{\partial {x}_{3}^{{}_{} 2}} + [ {k}^{{}_{} 2} - {k}_{2}^{{}_{} 2} ( \frac{{\overline{C}}_{66}}{{C}_{66}} ) ] {\tilde{u}}_{1} = 0 & ( 4 )\end{matrix}$$

Where Cᵢⱼ is the clastic stiffness constant, k=ω/v is the wavenumber of driving frequency, and v is the velocity for the propagation of the shear wave given by (C₆₆/ρ_{q})^{1/2}. C₆₆=C₆₆+e₂₆²/Σ₂₂ represents the acoustically stiffened elastic constant. By solving Equations 3 and 4, the resonance condition can be found for the electrode region using the following equation.

$$\\ \begin{matrix}\frac{{k}_{2} h}{( {k}_{26}^{{}_{} 2} + ( R / 2 ) {h}^{{}_{} 2} {k}_{2}^{{}_{} 2} )} = \frac{sin ( {k}_{2} h )}{cos ( {k}_{2} h )} & ( 5 )\end{matrix}$$

Where k₂₆²=e₂₆²/C₆₆ Σ₂₂ is the electrochemical coupling constant and R=(2 h′ρ′/hρ) is the electrode mass loading factor.

Solving the above equations for three different electrode configurations provides the electrode mass loading factor, which essentially determines the thickness (2 h′) of the electrode coating needed for quartz crystals. The optimized electrode thickness obtained from the mathematical model was then applied in the quartz crystal design.

### Quartz Crystal Design for Mass Sensitivity Measurements

In one embodiment, the present invention used blank quartz crystal resonators that were Plano-Plano AT-cut crystals with a diameter of 13.97 mm and a fundamental frequency of 6 MHz. In one embodiment, the blank quartz crystal resonator has a diameter between 13.90 mm to 14.10 mm. In one embodiment, the blank quartz crystal resonator has a diameter between 13.85 mm to 14.15 mm. In one embodiment, the blank quartz crystal resonator has a diameter between 13.80 mm to 14.20 mm. In one embodiment, the blank quartz crystal resonator has a diameter between 13.75 mm to 14.25 mm. In one embodiment, the blank quartz crystal resonator has a diameter between 13.70 mm to 14.30 mm. In one embodiment, the blank quartz crystal resonator has a diameter between 13.65 mm to 14.35 mm. In one embodiment, the blank quartz crystal resonator has a diameter between 13.60 mm to 14.40 mm. In one embodiment, the blank quartz crystal resonator has a diameter between 13.55 mm to 14.45 mm. In one embodiment, the blank quartz crystal resonator has a diameter between 13.50 mm to 14.50 mm.

In one embodiment, the crystals had beveled edges and optically polished surfaces. After cleaning with acetone, methanol, and deionized water for 5 minutes each, the crystals were dried with compressed nitrogen gas. In one embodiment, the photolithography technique was used to create keyhole and ring electrode patterns on the blank crystals. Then, a DC magnetron sputtering technique was used to deposit a gold layer pre-coated with titanium to enhance adhesion. In one embodiment, three configurations of resonators were examined: a keyhole with a mass loading factor of R=0.006, a ring electrode with a mass loading of R=0.006, a gold layer thickness of 111.2 nm, and a titanium layer with a thickness of 15 nm; and a modified ring electrode R=0.0045 with a gold layer thickness of 50 nm and titanium layer thickness of 500 nm. In one embodiment, the identical-concentric electrode (keyhole) had a radius of 2.5 mm for the upper and lower solid electrodes.

In one embodiment, the ring electrode QCR design had a solid lower ring electrode radius of 2.5 mm and upper ring electrode radius of 1 mm (inner) and 2.5 mm (outer). In one embodiment, the ring electrode QCR design had a solid lower ring electrode radius of between 2.4 mm-2.6 mm. In one embodiment, the ring electrode QCR design had a solid lower ring electrode radius of between 2.3 mm-2.7 mm. In one embodiment, the ring electrode QCR design had a solid lower ring electrode radius of between 2.2 mm-2.8 mm. In one embodiment, the ring electrode QCR design had a solid lower ring electrode radius of between 2.1 mm-2.9 mm. In one embodiment, the ring electrode QCR design had a solid lower ring electrode radius of between 2.0 mm-3.0 mm.

In one embodiment, ring electrode QCR design had the upper ring electrode having a radius of 1 mm (inner) and 2.5 mm (outer). In one embodiment, the upper ring electrode has a radius of between 0.9-1.1 mm (inner) and 2.4-2.6 mm (outer). In one embodiment, the upper ring electrode has a radius of between 0.8-1.2 mm (inner) and 2.3-2.7 mm (outer). In one embodiment, the upper ring electrode has a radius of between 0.7-1.3 mm (inner) and 2.2-2.8 mm (outer).

In one embodiment, the modified ring electrode had equal upper and lower ring electrodes with inner radii of 1 mm and outer radii of 2.5 mm. In one embodiment, the modified ring electrode bad equal upper and lower ring electrodes with inner radii of between 0.9-1.1 mm and outer radii of between 1.9-2.1 mm. In one embodiment, the modified ring electrode had equal upper and lower ring electrodes with inner radii of between 0.8-1.2 mm and outer radii of between 1.8-2.2 mm. In one embodiment, the modified ring electrode had equal upper and lower ring electrodes with inner radii of between 0.7-1.3 mm and outer radii of between 1.7-2.3 mm.

In one embodiment, the ring electrode has a gold layer thickness of between 110-112 nm, and a titanium layer with a thickness of between 14-16 nm. In one embodiment, the ring electrode has a gold layer thickness of between 108-114 nm, and a titanium layer with a thickness of between 13-17 nm. In one embodiment, the ring electrode has a gold layer thickness of between 106-114 nm, and a titanium layer with a thickness of between 12-18 nm. In one embodiment, the ring electrode has a gold layer thickness of between 104-116 nm, and a titanium layer with a thickness of between 11-19 nm. In one embodiment, the ring electrode has a gold layer thickness of between 102-118 nm, and a titanium layer with a thickness of between 10-20 nm. In one embodiment, the ring electrode has a gold layer thickness of between 100-120 om, and a titanium layer with a thickness of between 9-21 nm.

In one embodiment, the HC-48/U holder, having two micro-springs, was used to hold the crystal resonators. The holder is mounted on an x-y stage, allowing the crystals to move in a precise radial direction. In one embodiment, an ultra-fine-point Sharpie pen was used to place ink dots on the surface of the QCR devices. The pen was mounted on a z-stage to enable it to move vertically and apply the ink dots with consistent pressure, helping to minimize variations in dot mass. In one embodiment, an optical microscope with a digital camera was used to monitor the size of the ink dots. Frequency measurements were taken using a QCA922 instrument with a frequency scan range of 1 MHz to 10 MHz and a resolution of 0.1 Hz at a sampling rate of 100 ms. The mass of the ink dots was measured using a microbalance with a resolution of 10 μg.

### Mass Sensitivity Distribution Measurements

Most experimental methods that have been used to map the mass sensitivity distribution on a QCR surface, such as depositing a small metal spot or electroplating a wire tip on the crystal surface, have drawbacks. In contrast, the ink dot technique is a simple, effective, and reliable method for studying the radial dependence of mass sensitivity on the resonator surface. Additionally, the ink dot technique eliminates the stress and viscoelastic effect seen in other methods, so the recorded frequency shift is caused solely by the mass of the ink dots, which represents a rigid added mass.

In order to estimate the average mass of the ink dots, 130 dots were placed on the resonators, and the total weight of the dots, as measured by the microbalance, was approximately 100 μg. Therefore, the average mass of an individual ink dot was estimated to be 0.77±0.06 μg. The dot diameter was around 500 μm. To ensure accurate results, errors in dot position and mass were minimized by repeating the measurements several times at each location. The frequency shift (Δf) caused by each dot at each location was then recorded along radial direction. The ink dots dry rapidly, so all the frequency shift measurements were carried out at the same time interval after they were deposited each time.

### Circulating Tumor Cell Detection

Surface Modification of the Ring Electrode

In one embodiment, the central surface of the 9-MHz ring electrode QCR, made of SiO₂, was modified for use as a biosensor to capture CTCs. This was done by applying 3-Aminopropyltriethoxysilane (APTES) to the surface to aid in immobilizing anti-antibodies. A 2% APTES solution in toluene was used to decorate the surface of the ring electrode at room temperature and incubated for 2 hours in a nitrogen-rich atmosphere. Next, the surface was washed twice with the same solvent, followed by ethanol (2×), and then DI water to remove any physisorbed molecules, leaving only chemisorbed silane molecules on the surface. Finally, the surface was dried with compressed nitrogen and heated at 120° C. in an oven for 6 hours under a nitrogen atmosphere to improve the quality of the APTES decoration. In one embodiment, in order to efficiently capture cancer cells, the surface was further modified with anti-Epithelial cell adhesion molecule (EpCAM) antibodies.

In one embodiment, two methods of applying the antibodies were studied: direct and indirect.

In the direct method, the anti-EpCAM antibody was coupled directly and covalently to the APTES-decorated ring electrode surface using a zero-length cross-linker 1-Ethyl-3-[3-dimethylaminopropyl] carbodiimide hydrochloride (EDC)/N-hydroxy succinimide (NHS) reaction. First, 10 μL of anti-EpCAM antibody (0.1 mg/mL) diluted in phosphate-buffered saline (PBS) (0.1M, pH 7.4) was incubated with 10 μL of premixed EDC (5 μL of 0.4 mg/mL) and NHS (5 μL of 1.1 mg/mL) in 2-(N-morpholino) ethane sulfonic acid (MES) buffer solution (0.1M. pH 4.6) to activate the carboxyl groups on the anti-EpCAM antibody. Then, EDC/NHS-activated anti-EpCAM antibody was added to the freshly prepared APTES decorated ring electrode at room temperature with gentle shaking for 2 hours. Next, 1% bovine serum albumin (BSA) was added to the surface to block free sites and minimize non-specific reactions, shaking for 30 minutes. Finally, the surface was washed with PBS (2×) solution and washed with DI water (2×).

In the indirect method, the anti-EpCAM antibody was coupled to the APTES decorated surface via protein A/G, a recombinant fusion protein. First, 10 μL of protein A/G solution (1.0 mg dissolved in 1.0 mL of 10 mM phosphate buffer, pH 7.4, and 1.0 mL of 10 mM Na-acetate buffer, pH 5.5) was activated by adding 10 μL of premixed EDC (5 μL of 4 mg/mL) and NHS (5 μL of 11 mg/mL) in MES buffer solution (0.1M, pH 4.6) for 15 minutes at room temperature. Then, the EDC/NHS-activated protein A/G solution was applied to the APTES decorated ring electrode and incubated for 60 minutes at room temperature. This procedure allows protein A/G to be bonded covalently to the ring electrode surface. Next, excess unbonded A/G protein was removed by washing the surface with PBS solution (2×). After that, 10 μL of EDC/NHS-activated anti-EpCAM antibody (0.1 mg/mL) was applied to the surface at room temperature with gentle shaking for 1 hour. Finally, the surface was washed with PBS solution (2×) and washed with DI water (2×).

### Quartz Crystal Holder Design and Fabrication

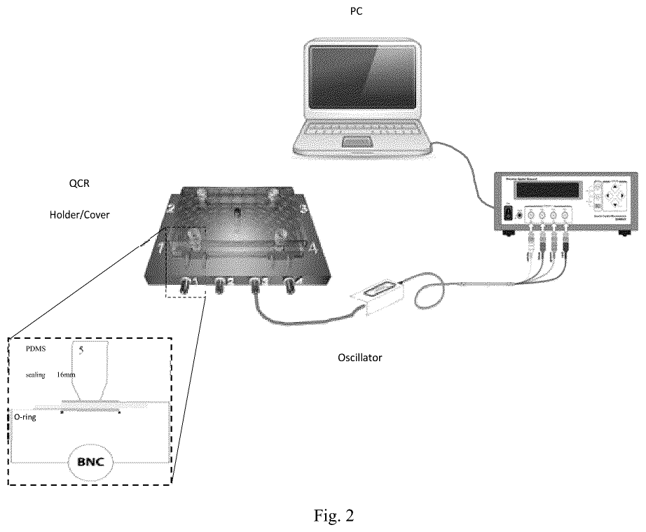

In one embodiment, the PDMS polymer, having two components, produced a unique scaling design for confining circulating tumor cells (CTCs) in the central area of the QCR surface, 1.5 mm in diameter. The crosslinker/curing agent mix was chosen for its biocompatibility and easy formability, with a component ratio of 1:10 by weight proven to provide excellent mechanical and elastic properties. In one embodiment, after mixing the PDMS components, the blend was degassed in a desiccator for 60 minutes to remove any trapped bubbles. Meanwhile, a casting mold was constructed using a self-locking microcentrifuge tube with a 2 mL volume. A hole of 1.5 mm diameter was created in the bottom of the tube by drilling, and a 200 μL tip was inserted through the hole. The PDMS mix was poured into the tube and left in the desiccator to dry for 24 hours. Next, the dried PDMS was removed from the mold, cut to the required size, and annealed in an oven at 150° C. for 24 hours. The steps for preparing the PDMS sealing design are shown in FIG. 2. In one embodiment, the final product was sonicated in toluene for 30 minutes to remove unbound molecules, then annealed for 48 hours. Finally, the PDMS scaling design was mounted on the four corners of a 96-well microplate cover using epoxy adhesive, creating the final QCR cover design as shown in FIG. 2.

Conducting experiments with cancer cells requires repeating the process multiple times in order to obtain reliable results and reduce errors. Therefore, a practical and cost-effective quartz crystal resonator (QCR) sensor holder is essential. To achieve this, a holder with four crystals was made, allowing multiple experiments to be conducted simultaneously under the same conditions. First, HC-48/U holders, consisting of two micro-springs, were mounted on each corner of the plastic base using quick-drying epoxy adhesive. The holder contact clips were then soldered to the male BNCs mounted on the side of the holder base. Finally, the QCR was sealed between a Teflon-coated silicone O-ring (below) and a PDMS sealing design cover (above). FIG. 2 shows a representation of the final QCR base holder design.

### Biosensor Measurements

In one embodiment, three cancer cell lines-MCF-7, PANC-1, and PC-3—are used to test the efficiency of the fabricated biosensor. These cell lines were chosen because their strong adhesion to the gold surface and the APTES-decorated anti-EpCAM modified SiO₂ surface. In each experiment, four crystals were mounted on the holder and then connected to the QCA922 analyzer to record each crystal's first reading of the frequency (F1) and resistance (R1) in the air. Two resonators served as the control (reference), incubated with 50 μL of pure media. The other two resonators, tested for efficiency, were incubated with 50 μL containing 100-500 cancer cells. The holder was then placed inside an incubator for 30 minutes to allow the cells to attach to the QCR surface. After the cells were attached, they were fixed with 50 μL of 0.04% paraformaldehyde for 15 minutes. Next, the QCRs were washed gently with BPS (1×) once and with warm DI water (3×). The crystals were left for a couple of hours to dry, then a second reading of the frequency (F2) and resistance (R2) was recorded in the air, and the frequency/resistance shifts were calculated (ΔF=F2−F1, ΔR=R2−R1). In each experiment, the reference reading value was subtracted.

In one embodiment, the attached cells were stained with Alexa Fluor 488 phalloidin and 4′,6-diamidino-2-phenylindole (DAPI) to count the number of cells attached and calculate the total area. First, the fixed cells were permeabilized in 1% Triton X-100 for 5 minutes, then washed three times with PBS for 5 minutes each. Next, cells fixed on the sensor were incubated with 1% BSA for 30 minutes to block nonspecific binding and then rinsed once with PBS. Next, 200 μL (165 nM) of phalloidin was added to the cells for 60 minutes at room temperature in the dark; then, the cells were washed twice with PBS. After that, 200 μL (300 nM) of DAPI was added to the sensor for 10 minutes, then rinsed with PBS and DI water twice. Lastly, the QCRs were removed from the holder for observation under a fluorescence microscope. ImageJ software was used to determine the total number of cells attached and the total coverage area on the QCR.

### Results and Discussion

### Mass Sensitivity Distribution Measurements

FIG. 3 panel (a) shows a comparison of mass sensitivity distribution of 6-MHz Plano-Plano resonator for keyhole design (R=0.006), ring electrode (R=0.006), and modified ring electrode (R=0.0045). Calculated and experimental data of mass sensitivity distribution as a radial location from the center of 6-MHz Plano-Plano resonator designs are shown in panel (b) keyhole (m-m) (R=0.006), in panel (c) ring electrode (R=0.006), and in panel (d) modified ring electrode (R=0.0045). FIG. 3 panel (a) compares the frequency response as a function of radial distance from the center of the crystal for the keyhole electrode, a ring electrode, and modified ring electrode QCRs, all using a 6-MHz Plano-Plano crystal as obtained by our mathematical model. As expected, the keyhole QCR configuration with a mass loading factor of R=0.006 had the highest mass sensitivity in the center (around 9.25×1011 Hz/kg) due to the high energy trapping in the center of the crystal. The ring electrode QCR configuration with a mass loading factor of R=0.006 showed lower mass sensitivity (around 5.8×1011 Hz/kg) with a uniform mass distribution along the partial electrode region. The modified ring electrode with a mass loading factor of R=0.0045 displayed slightly lower mass sensitivity (around 5.5×1011 Hz/kg) and a uniform mass sensitivity distribution in the electrode region compared to the ring electrode configuration. The maximum reduction in mass sensitivity was 37.3% and 40.5% for the ring electrode and modified ring electrode QCRs, respectively, compared to the keyhole electrode QCR.

FIG. 3 panels (b) (c) (d) compare the measured and predicted differential mass sensitivity of the three QCR designs as a function of radial distance. As expected for the keyhole design with a loading factor of R=0.006, 110.2 nm gold, and 15 nm titanium, the Gaussian profile is clear, and the mass sensitivity drops gradually towards the edges of the electrode, as shown in FIG. 3 panel (b). This is because the energy is mainly confined in the center of the electrode due to energy trapping. On the other hand, for the ring electrode design with the same loading factor, an inner ring diameter of 2 mm, and an outer diameter of 5 mm, the mass sensitivity in the central 2 mm produces a flat response. Similarly, the modified ring electrode shows a flat region when the mass loading is around R=0.0045, as shown in FIG. 3 panel (c). In other words, the center region of these designs (inner diameter: 2 mm) has the same mass sensitivity everywhere in this area because the acoustic waves have equal amplitude at each point (mass sensitivity is proportional to the square of local wave amplitude). FIG. 3 clearly shows that the measured mass sensitivity data followed the predicted trends based on the present invention's model for all designs. The slight deviation between measured and predicted data may be due to the error in measuring the exact mass and radial location of the ink dots on the resonator surface each time. Though this effect was minimized in the setup, some errors cannot be avoided. Overall, the experimental data agreed with the predicted mass sensitivity and showed the same trend. The ink dot method is affordable and accurate, making it very attractive for examining and calibrating the mass sensitivity of any QCR design.

### Cancer Cell Detection

The present invention chose to study the efficiency of cancer cell detection using a 9 MHz ring electrode because this electrode configuration showed the highest frequency response in ink-dot testing as well as flat frequency response as a function of radial distance, as described above. In one embodiment, the present invention compared the efficiency of the ring electrode QCR (9 MHz) to that of a commercially available 6 MHz keyhole electrode QCR, which is commonly used for measuring thin film thickness in physical vapor deposition. While 9 MHZ QCRs have a higher intrinsic frequency than 6 MHz QCRs for a given mass change, the present invention has demonstrated the difference in the spatial distribution of frequency response between commercially available keyhole electrodes and the model-based ring electrodes of the present invention. Thus, the difference in intrinsic frequencies between 6 MHz and 9 MHZ QCRs does not affect the main focus of the present invention.

### Capture Efficiency of Anti-EpCAM Immobilized APTES Decorated Ring Electrode QCR

The performance of cell-detecting biosensors largely depends on the effectiveness of the selective layer immobilized on the biosensor surface. Therefore, to enhance the ability of a QCR biosensor to capture circulating tumor cells (CTCs), it is ideal for immobilizing an anti-EpCAM antibody layer in a way that makes its active sites easily accessible for interaction with the antigens on targeted CTCs. To evaluate capture efficiency, in one embodiment, the present invention has used MCF-7 cells as a test sample, which have a high expression of EpCAM, promoting binding to the immobilized anti-EpCAM antibody, for testing on APTES-decorated ring electrode QCR immobilized by direct and indirect methods.

FIG. 4A illustrates the percentage of MCF-7 cells captured by the ring electrode QCR biosensor based on the mean values of three experiments. The control QCR, an APTES-decorated ring electrode QCR without an anti-EpCAM antibody coating, had the lowest number of attached cancer cells among the three tested QCRs. The QCR with anti-EpCAM applied using the direct method showed a slight increase in the number of captured cells, followed by the highest number of cells captured on the QCR with anti-EpCAM applied using the indirect method. The low number of captured cells on the control QCR can be attributed to non-specific interaction between the MCF-7 cells and the QCR surface. On the other hand, in the case of the direct immobilization method, many of the anti-EpCAM antibodies bond covalently to the APTES layer through antigen-binding active regions, as represented schematically in FIG. 4B. As a result, the antibodies lose their activity to capture cancer cells, which can explain the lower capture efficiency. The antibodies must maintain their activity during immobilization on solid surfaces to maximize biosensor efficiency.

The indirect immobilization method of the APTES-decorated ring electrode QCR device using protein A/G mediated anti-EpCAM antibody overcomes the limitation of random antibody orientation and shows the highest capture efficiency. The recombinant protein A/G is a genetically engineered protein that combines the IgG binding domains of protein A and protein G, which are extracted from the surfaces of staphylococci and streptococci. The protein A/G specifically binds to the Fc domain of various subclasses of IgG, and the advantage of using this protein mixture compared to individual proteins A or G is that it covers almost the whole range of the subclasses of IgG and is less sensitive to pH variations. Therefore, this protein mixture is bonded covalently to the APTES-decorated QCR biosensor to help maintain the activity of the anti-EpCAM antibody. Increasing the efficiency of the QCR biosensor coated by the indirect method confirms that the anti-EpCAM antibody layer is well-oriented on the sensing area of the QCR biosensor, as shown in FIG. 4B, which promotes antibody-antigen binding. The well-orientation of the anti-EpCAM antibodies is related to the strong affinity bonding between the Fc domains of the anti-EpCAM antibodies and the protein A/G deposited on the biosensor surface. This facilitates the attachment of MCF-7 cells to the biosensor surface through antibody-antigen interaction, resulting in the highest capture efficiency.

### Spatial Sensitivity Measurements

In one embodiment, the present invention studied the frequency response of the APTES-decorated ring electrode QCR using an indirect method for immobilizing anti-EpCAM for three cancer cell lines, as they had the potential to capture the highest number of cancer cells. In one embodiment, the present invention has also examined the frequency response of the keyhole QCR for the same three cancer cell lines and compared the results with the ring electrode to evaluate the effectiveness of the electrode design.

FIG. 5 displays representative fluorescence images of attached cancer cells. The present invention has captured several fluorescence images for each cell line for each design and used them to count the number of cells attached to the surfaces. In particular, panel (a) shows fluorescence images of three different cancer cell lines attached and fixed to the 6-MHz keyhole QCR and panel (b) shows fluorescence images of three different cancer cell lines attached and fixed to the 9-MHz ring electrode QCR, each with an incubation time of 30 minutes and a magnification of 40×. The images represent a random area (scale of 20 microns) on the active regions of the quartz crystals and do not represent the total number of captured cells.

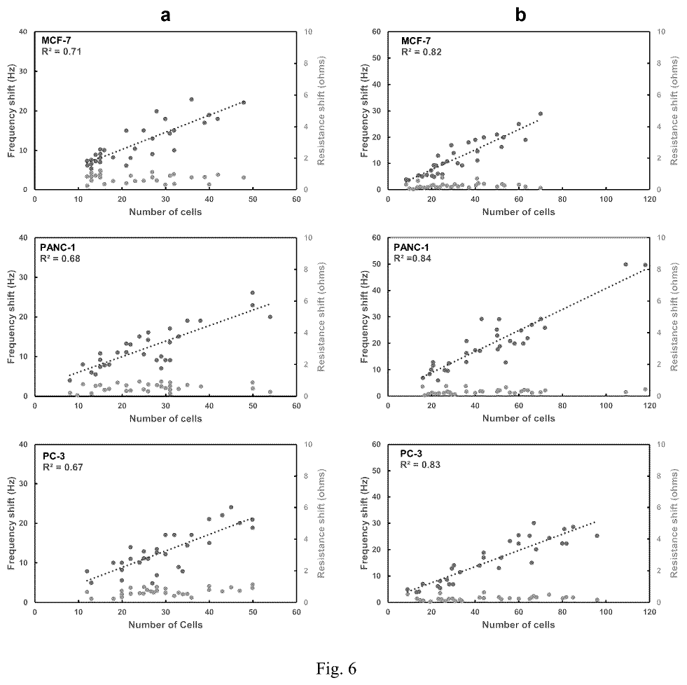

FIG. 6 illustrates the frequency shift as a function of the number of captured cells for the three cell lines for both electrode designs: panel (a) for 6-MHz keyhole electrode QCR, and panel (b) for 9 MHz ring electrode QCR. The frequency shift of both designs is proportional to the number of attached cells, as an increase in the number of attached cells increases the frequency shift. The average frequency shift caused by a single cell in the case of the 6 MHZ keyhole QCR was approximately 0.39±0.09 Hz, 0.42±0.10 Hz, and 0.32±0.08 Hz for the MCF-7, PANC-1, and PC-3 cell lines, respectively. Similarly, the average frequency shift caused by a single cell was around 0.48±0.12 Hz, 0.49±0.17 Hz, and 0.46±0.11 Hz for the MCF-7, PANC-1, and PC-3 cell lines, respectively, in the case of the APTES-decorated 9-MHz ring electrode QCR. The value of R2, which measures the goodness of the linear regression fit, was found to be much higher for the APTES-decorated 9-MHz ring electrode QCR, ranging from 0.82 to 0.84 for different cell lines, compared to 0.67 to 0.71 for the 6 MHz keyhole QCRs.

The significantly higher R² value indicates that the spatial variation in the mass of the cells is minimized for the APTES-decorated 9-MHz ring electrode QCR. As a result, the frequency change is caused only by the added mass, and there is no effect due to the location of the CTCs on the surface of the ring electrode QCR. In the case of the keyhole design, the significantly lower R² was likely caused by two factors: the different cell size distribution and the random location of the cells on the surface of the keyhole QCR. However, it is safe to say that the lower R² is mainly due to the spatial nonuniformity of the keyhole electrode design. As seen in FIG. 5, the size of the captured cancer cells is comparable in both electrode designs, i.e., the keyhole and the ring electrode designs. From the ink dot experiments of the present invention, it was observed that the keyhole electrodes showed a Gaussian spatial distribution of frequency response for the exact size of ink dots along the axis of the QCR. It is well-known that the sensitivity of the keyhole QCR is very high in the central area of the electrode due to energy trapping, and any shift from the center will cause a significant variation in frequency. Therefore, when CTCs are attached very close to the center of the electrode, a higher frequency response is expected compared to CTCs attached at a distance away from the center of the electrode, which will produce a lower frequency response.

For both designs, the resonance resistance shift (ΔR) is negligible and does not show an increase with an increase in the number of attached cells. This trend in resonance resistance confirms that fixed CTCs to the QCR surface behave as rigid and non-viscous, indicating that the frequency shift is caused only by the mass of the CTCs.

Therefore, the present invention concludes that the model-based ring electrode successfully eliminates the spatial nonuniform frequency response and has enormous potential in commercializing POC tools for early cancer detection. This result is significant because the present invention achieved spatial uniformity of frequency distribution without compromising the frequency sensitivity by using the first harmonic modes of the QCR compared to other works that used higher harmonic modes, such as 3rd, 5th, and 7th, which reduces the frequency sensitivity. Although more studies are required to fine-tune the design due to the complexity involved in detecting cancer cells at an early stage, such as the rapid growth of cancer cells and splitting of cancer cells, the ring electrode design is the first step in such an endeavor.

### Conclusions

In summary, the present invention have demonstrated the detection of circulating tumor cells (CTC) using quartz crystal resonators (QCRs), which could change the way cancer screening is performed in the future. The mathematical model was employed to predict the mass sensitivity behavior of commercially available keyhole electrode QCRs, and it was compared to the designs of the ring electrode and modified ring electrode QCRs. The mathematical model was used to optimize the thickness of the electrodes, which is crucial in confining the acoustic wave propagation within the electrode area with equal amplitude at each point, thus eliminating spatial non-uniformity in the first harmonic mode of QCRs. The present invention has demonstrated significant advantages over previous works that achieved uniform spatial mass sensitivity at higher harmonic modes but at the cost of a lower quality factor, which reduced overall sensitivity.

The present invention has tested the ring electrode QCR for its ability to detect three different cancer cell lines by measuring the uniform spatial frequency shift. An indirect method of modifying the surface of the QCR using protein A/G-mediated anti-EpCAM antibodies was developed to maximize the capture of cancer cells, which is a crucial factor in increasing the frequency shift. The results showed that the ring electrode QCRs of the present invention performed better than commercially available keyhole electrodes for all three cancer cell lines tested.

### Mathematical Model

The angular resonance frequency ωₒ^{e} for the electrode region can be found by solving Equation 5 for k₂, as follows.

$${ω}_{o}^{e} = \frac{π}{2 h} {( \frac{{\hat{C}}_{66}^{E}}{ρ} )}^{1 / 2} \qquad ( 6 a )$$

The angular resonance frequencies ωₒ^{p}, ωₒ^{u} on both the partially and non-electrode regions can be obtained by the same method.

$${ω}_{o}^{p} = \frac{π}{2 h} {( \frac{{\hat{C}}_{66}^{P}}{ρ} )}^{1 / 2} \qquad ( 6 b )$$

$${ω}_{o}^{u} = \frac{π}{2 h} {( \frac{{\overline{C}}_{66}}{ρ} )}^{1 / 2} \qquad ( 6 c )$$

Where

$${\hat{C}}_{66} = {\overline{C}}_{66} ( 1 - 2 R - \frac{8 {k}_{26}^{2}}{{π}^{2}} )$$

is the piezoelectrically stiffened effective elastic constant. For AT-cut quartz crystal, the electromechanical coupling factor is very small (k₂₆²≈0.8%). Therefore, the piezoelectric effect of the electrode is negligible compared to the mass loading effect when

$$R ≫ \frac{4 {k}_{26}^{2}}{{π}^{2}} .$$

According to the latter relation of Ĉ66, increasing the mass loading factor and reducing the piezoelectrically stiffened effective elastic constant make the resonance frequency, particularly the cut-off frequency, of the electrode region lower than that of both the partially coated and uncoated regions.

For convenience, Equation 4 can be converted from the Cartesian coordinate system to the polar coordinate system (r,θ) to match the boundary conditions of a cylindrical resonator. Therefore, the particle displacement amplitude across the QCR can be described in cylindrical coordinates by applying a scalar Helmholtz wave equation.

$${r}^{2} \frac{{\partial }^{2} {A}_{1} ( r , θ )}{\partial {r}^{2}} + r \frac{\partial {A}_{1} ( r θ )}{\partial r} + \frac{{\partial }^{2} {A}_{1} ( r , θ )}{\partial {θ}^{2}} + {( {rk}_{r} )}^{2} {A}_{1} ( r , θ ) = 0 \qquad ( 7 )$$

The first two terms in Equation 7 shows variation along the radial direction (r) which represents Bessel's differential equation, whose solution can be given by Bessel functions. While the third term shows variation in the angular direction (θ) which represents angular function equation whose solution can be given by harmonie functions. Therefore, the general solutions of Eq. 7 will be in the form.

$${A}_{1} ( r , θ ) = \{ \begin{matrix}{\sum }_{n = 0}^{n = ∞} [ C 1 {J}_{n} ( {k}_{r} r ) + C 2 {N}_{n} ( {k}_{r} r ) ] [ C 3 cos n θ + C 4 sin n θ ] \\ {\sum }_{n = 0}^{n = ∞} [ C 1 {I}_{n} ( {k}_{r} r ) + C 2 {K}_{n} ( {k}_{r} r ) ] [ C 3 cos n θ + C 4 sin n θ ]\end{matrix} \qquad ( 8 )$$

Where kᵣ²=k²−k_{c}², kᵣ is the radial wavenumber, k_{c} is the cutoff wavenumber given by

$${k}_{c}^{2} = {k}_{2}^{2} ( \frac{{\overline{C}}_{66}}{{\overline{C}}_{66}} ) ,$$

and n is the harmonic constant with values 0, 1, 2, 3, . . .

Note that, the radial acoustic wavenumber k, becomes imaginary (is <0) when k<k_{c}. This will result in an evanescent acoustic wave that exponentially decays when it is far away from the electrode region. In contrast, when k, k_{c}, kᵣ becomes real (>0), resulting in an acoustic wave energy that spreads over the entire quartz plate and no evanescent acoustic wave.

C1, C2, C3 and C4 are unknown amplitude constants that can be found by applying the boundary condition. Iₙ(kᵣr) is the Bessel function of the first kind with order n, which has a finite limit as (kᵣr) reaches zero. Nₙ(kᵣr) is the second kind of Bessel function, with order n, and does not have a finite limit as (kᵣr) reaches zero. Iₙ(kᵣr) and Kₙ(kᵣr) are, respectively, the first and second modified Bessel functions (order: n). Kₙ(kᵣr) has no finite limit, but In (kᵣr) has a finite limit as (kᵣr) nears zero.

When the QCR operates at a fundamental resonance mode, n=0, the particle displacement amplitude varies in the radial direction (r) and does not vary in the angular direction (θ). Therefore, Eq. 8 can be rewritten as follows:

$${A}_{1} ( r ) = \{ \begin{matrix}C 1 {J}_{o} ( {k}_{r} r ) + C 2 {N}_{o} ( {k}_{r} r ) & {( {k}_{r} r )}^{2} > 0 \\ C 1 {I}_{o} ( {k}_{r} r ) + C 2 {N}_{o} ( {k}_{r} r ) & {( {k}_{r} r )}^{2} < 0\end{matrix} \} \qquad ( 9 )$$

Where Jₒ and Nₒ represent the Bessel function of the first and second kind with order zero, and Iₒ and Kₒ represent the modified Bessel function of the first and second kind with order zero. The constants C1 and C2 represent the particle amplitudes. The correct solution can be chosen depending on the condition of the Bessel function.

Because each region of the crystal has a different cut-off frequency, the radial component can be written in terms of operating frequency (f) and cut-off frequency (f_{c}) for each region.

$$n {ik}_{r}^{2} = \{ \begin{matrix}( \frac{{π}^{2}}{4 {h}^{2}} ) ( \frac{1}{{f}_{66}^{2}} ) [ {f}^{2} - {f}_{ce}^{2} ] \\ ( \frac{{π}^{2}}{4 {h}^{2}} ) ( \frac{1}{{f}_{66}^{2}} ) [ {f}^{2} - {f}_{cp}^{2} ] \\ ( \frac{{π}^{2}}{4 {h}^{2}} ) ( \frac{1}{{f}_{66}^{2}} ) [ {f}^{2} - {f}_{cu}^{2} ]\end{matrix} \} \qquad ( 10 )$$

Where f_{ce}, f_{cp}, and f_{cu} are the cut-off frequencies in full electrode, partially electrode, and non-electrode regions, respectively, while f₆₆ represents the cut-off frequency in the quartz crystal plate. The radial components can be calculated using the cut-off frequency for each region, which in turn allows the particle displacement amplitudes on each region to be found.

a) Concentric identical-electrode QCR (m-m)

The concentric identical-electrode QCR (m-m) structure is considered the simplest and most common configuration of QCR devices, as shown in FIG. 2. The m and m represent the upper and lower solid electrodes, which have the same diameter. In this QCR configuration, only electrode and non-electrode regions exist. The excited acoustic wave on the crystal surface is largely confined within the electrode region (0 gr s′a), so the convenient operating frequency will fall between cut-off frequencies on non-electrode and fully electrode regions i.e. f_{cu}>f>f_{ce}.

By simplifying Equation 9, the particle displacement in each region can be found using the following equation.

$${A}_{1} ( r ) = \{ \begin{matrix}C 1 {J}_{o} ( {k}_{r}^{e} r ) & 0 \leq r \leq a \\ C 1 {K}_{o} ( {k}_{r}^{u} r ) & a \leq r \leq ∞\end{matrix} \} \qquad ( 11 )$$

During vibration, the central particle displacement amplitude in the center of the electrode region is assigned a finite value (A₁) representing the maximum vibration. At the center (r=0), the Bessel function of the second kind (Nₒ) is undefined by virtue of its singularity, and, therefore, it is discarded as a solution to Eq. 9. Hence, C2-0. Because the resonator is clamped at the edge, the particle displacement amplitude will vanish at the edge of the resonator. So, in the non-electrode region, the modified Bessel function of the first kind (Iₒ) cannot be a solution to Eq. 9 because the function is undefined by virtue of its singularity (goes to infinity) when r→∞. Hence, C1=0.

The remaining C1 and C2 in Eq. 11 are the particle displacement amplitude constants and can be found by applying the following boundary conditions in each region: 1) the continuity of the particle displacement A₁ and 2) the continuity of the shear strain field ∂r/∂A₁ at r=a for the electrode and non-electrode regions.

### b) Ring Electrode QCR

The ring electrode QCR structure consists of a lower solid electrode with radius b and an upper ring electrode with inner and outer radii a and b, respectively. This QCR configuration includes three regions: full electrode, partial electrode, and non-electrode, as shown in FIG. 2b. Depending on the operating frequency conditions, the excited acoustic waves either exist within both the electrode and partial electrode regions f_{cu}>f>f_{cp}>f_{ce} or are confined to the electroded region f_{cu}>f_{cp}>f>f_{ce}.

By simplifying the solution of Equation 9, one gets the following:

$${A}_{1} ( r ) = \{ \begin{matrix}C 1 {I}_{o} ( {k}_{r}^{p} r ) & 0 \leq r \leq a \\ C 2 {J}_{o} ( {k}_{r}^{e} r ) + C 3 {N}_{o} ( {k}_{r}^{e} r ) & a \leq r \leq b \\ C 4 {K}_{o} ( {k}_{r}^{u} r ) & b \leq r < ∞\end{matrix} \} \qquad ( 12 )$$

In the partially electrode region, the modified Bessel function of the second kind (Kₒ) is excluded because the function has singularity at the origin (r=0). The modified Bessel function of the first kind (Iₒ) has been discarded in the non-electrode region because the Bessel function Iₒ→∞ when r→∞. In the electrode region, Bessel functions of both the first and second kinds exist (a≤r≤b). By applying the same boundary conditions as for the identical-electrode QCR (m-m), Eq. 12 will yield four linear homogenous equations, which can be rearranged as a matrix:

$$[ \begin{matrix}{I}_{o} ( {k}_{r}^{p} a ) & - {J}_{o} ( {k}_{r}^{e} a ) & - {N}_{o} ( {k}_{r}^{e} a ) & 0 \\ {k}_{r}^{p} {I}_{1} ( {k}_{r}^{p} a ) & {k}_{r}^{e} {J}_{1} ( {k}_{r}^{e} a ) & {k}_{r}^{e} {N}_{1} ( {k}_{r}^{e} a ) & 0 \\ 0 & {J}_{o} ( {k}_{r}^{e} b ) & {N}_{o} ( {k}_{r}^{e} b ) & - {K}_{o} ( {k}_{r}^{u} b ) \\ 0 & - {k}_{r}^{e} {J}_{1} ( {k}_{r}^{e} b ) & - {k}_{r}^{e} {N}_{1} ( {k}_{r}^{e} b ) & {k}_{r}^{u} {K}_{1} ( {k}_{r}^{u} a )\end{matrix} ] [ \begin{matrix}C 1 \\ C 2 \\ C 3 \\ C 4\end{matrix} ] = 0 \qquad ( 13 )$$

Eq. 13 yields a nontrivial solution when the determinant of the matrix vanishes. The matrix of the particle amplitude constants (C1, C2, C3, C4) cannot be a zero trivial solution; therefore, the matrix on the left must equal zero. Using these parameters, the particle amplitude constants (C1, C2, C3, C4) can be found and utilized to calculate the radial dependence of differential mass sensitivity (Eq. 2).

### c) Modified Ring Electrode QCR

In this design, the upper and lower electrodes have the same dimensions of ring electrodes. The structure of the modified ring electrode QCR consists of three regions. The first region (I) is full electrode in the center of the QCR and has one metal layer (Ti), the second region (II) is full electrode with two different metal layers (Ti/Au), and the third region (III) is non-electrode, as shown in FIG. 2c. The cut-off frequencies of these regions can be defined as f_{cel}, f_{cell}, and f_{cu}, respectively. The excited acoustic waves could exist in any region depending on the operating frequency conditions; herein, the acoustic wave will be confined to electrode regions I and II, so the following condition applies: f_{cu}>f>f_{cel}>f_{cell}.

The mass loading factors for both regions can be given by the following equation.

$${R}_{I} = ( \frac{2 {h}^{″} {ρ}^{″}}{h ρ} ) \qquad ( 14 a )$$

$${R}_{II} = ( \frac{2 {h}^{′} {ρ}^{′}}{h ρ} ) + ( \frac{2 {h}^{″} {ρ}^{″}}{h ρ} ) \qquad ( 14 b )$$

$$R = {R}_{I} + {R}_{II} \qquad ( 14 c )$$

Where Rₗ and Rₗₗ are the mass loading factors of regions I and II, respectively, 2 h″, p″, 2 h′, and p′ are the thickness and density of regions I and II, respectively. Herein, R represents the total mass loading factor in both regions (I and II) for a modified ring electrode.

The solution for this configuration is as follows:

$${A}_{1} ( r ) = \{ \begin{matrix}C 1 {J}_{o} ( {k}_{r}^{eI} r ) & 0 \leq r \leq a \\ C 2 {J}_{o} ( {k}_{r}^{eII} r ) + C 3 {N}_{o} ( {k}_{r}^{eII} r ) & a \leq r \leq b \\ C 4 {K}_{o} ( {k}_{r}^{u} r ) & b \leq r < ∞\end{matrix} \} \qquad ( 15 )$$

Where kᵣ^{el}, kᵣ^{ell}, kᵣ^{u} are the radial components for regions I, II, and III, respectively.

According to Eq. 15 and by applying the boundary conditions, four linear homogenous equations are produced and can be rearranged as a matrix:

$$[ \begin{matrix}{J}_{o} ( {k}_{r}^{eI} a ) & - {J}_{o} ( {k}_{r}^{eII} a ) & - {N}_{o} ( {k}_{r}^{eII} a ) & 0 \\ - {k}_{r}^{eI} {J}_{1} ( {k}_{r}^{eI} a ) & {k}_{r}^{eII} {J}_{1} ( {k}_{r}^{eII} a ) & {k}_{r}^{eII} {N}_{1} ( {k}_{r}^{eII} a ) & 0 \\ 0 & {J}_{o} ( {k}_{r}^{eII} b ) & {N}_{o} ( {k}_{r}^{eII} b ) & - {K}_{o} ( {k}_{r}^{u} b ) \\ 0 & - {k}_{r}^{eII} {J}_{1} ( {k}_{r}^{eII} b ) & - {k}_{r}^{eII} {N}_{1} ( {k}_{r}^{eII} b ) & {k}_{r}^{u} {K}_{1} ( {k}_{r}^{u} a )\end{matrix} ] [ \begin{matrix}C 1 \\ C 2 \\ C 3 \\ C 4\end{matrix} ] = 0 \qquad ( 16 )$$

Similar to Eq. 13, when the determinant of the matrix vanishes, Eq. 16 yields a nontrivial solution. Since the matrix of the particle amplitude constants (C1, C2, C3, C4) cannot be a zero trivial solution, the matrix on the left must equal zero. Again, by using these parameters, the particle amplitude constants (C1, C2, C3, C4) can be found and utilized to calculate the radial dependence of differential mass sensitivity (Eq. 2).

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference was individually incorporated by reference.

What is claimed is:

1. A quartz crystal resonators (QCR) used as a sensor for quantitatively detection of a target, comprising:
a first electrode;
a second electrode;
a quartz wafer disposed between the first electrode and the second electrode;
an immobilizing agent disposed on a surface of at least one of the first electrode and the second electrode; and
a binding agent in association with the immobilizing agent,
wherein the binding agent binds to the target.

2. The QRC of claim 1, wherein the first electrode comprises a ring configuration; and wherein the ring configuration has a ring configuration outer diameter and a ring configuration inner diameter.

3. The QRC of claim 2, wherein the ring configuration outer diameter is about 2.5 mm, and the ring configuration inner diameter is about 1 mm.

4. The QRC of claim 2, wherein the second electrode comprises a round configuration.

5. The QRC of claim 4, wherein the round configuration has a round configuration diameter about 2.5 mm.

6. The QRC of claim 2, wherein the second electrode comprises the ring configuration.

7. The QRC of claim 6, wherein the QRC further comprises a first sub-electrode disposed between the first electrode and the quartz wafer; and a second sub-electrode disposed between the second electrode and the quartz wafer.

8. The QRC of claim 1, wherein the target comprises at least one of cells, microbials, and large biological molecules; wherein the large biological molecules comprise proteins, DNAs, and RNAs.

9. The QRC of claim 8, wherein the target comprises circulating tumor cells.

10. The QRC of claim 1 wherein the immobilizing agent comprises 3-Δminopropyltriethoxysilane (APTES).

11. The QRC of claim 1, wherein the binding agent comprises an antibody.

12. The QRC of claim 11 further comprises a linking agent; wherein the linking agent connect a Fc region of the antibody to the immobilizing agent.

13. The QRC of claim 12, wherein the linking agent comprises a fusion protein A/G.

14. The QRC of claim 1, wherein each of the first electrode and the second electrode comprises a gold layer.

15. The QRC of claim 1, wherein the gold layer of each of the first electrode and the second electrode are coated with titanium.

16. The QRC of claim 14, wherein the gold layer has a thickness between about 50 nm to about 120 nm.

17. A method for quantitatively detection of a target using a quartz crystal resonators (QCR), comprising:
obtaining a first frequency reading of the QCR;
exposing a sample containing the target to the QCR;
incubating the QCR in association with the sample containing the target for an incubation period;
fixing the target onto the QCR;
washing the QCR with the fixed target;
drying the QCR with the fixed target; and
obtaining a second frequency reading of the QCR with the fixed target;
wherein the QCR comprises a first electrode; a second electrode; a quartz wafer disposed between the first electrode and the second electrode; an immobilizing agent disposed on a surface of at least one of the first electrode and the second electrode; and a binding agent in association with the immobilizing agent; wherein the binding agent binds to the target.

18. The method of claim 17 further comprises calculating a frequency shift by subtracting the first frequency reading from the second frequency reading.

19. The method of claim 17, wherein the first electrode comprises a ring configuration; wherein the ring configuration comprises a ring configuration outer diameter and a ring configuration inner diameter; and wherein the second electrode comprises a round configuration.

20. The method of claim 19, wherein the target comprises circulating tumor cells.

21. The QRC of claim 1, wherein the target comprises a non-biological target, wherein the non-biological target comprises at least one organic molecule.
